(19) United States
(12) Patent Application Publication
(10) Pub. No.: US 2026/0164946 A1
(43) Pub. Date: Jun. 11, 2026

(54) DISPLAY SUBSTRATE AND MANUFACTURING METHOD THEREOF, DISPLAY DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Ying HAN, Beijing (CN); Pan XU, Beijing (CN); Cheng XU, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/708,808

(22) PCT Filed: Apr. 18, 2023
(86) PCT No.: PCT/CN2023/088913

§ 371 Date: May 9, 2024

(51) Int. Cl. H10K 59/123; H10K 59/12

(52) U.S. Cl. CPC H10K 59/123; H10K 59/1201

(57) ABSTRACT

A display substrate and a manufacturing method thereof, and a display device are provided. In the display substrate, at least one first transmission portion extends in a second direction, a plurality of connection via holes are provided in the insulating layer, and the at least one first transmission portion is electrically connected with at least one second transmission portion through at least one connection via hole, an orthographic projection of at least a portion of an edge of the at least one first transmission portion extending in the second direction on the base substrate falls into an orthographic projection of the connection via hole on the base substrate.

### TECHNICAL FIELD

At least one embodiment of the present disclosure relates to a display substrate and a manufacturing method thereof, and a display device.

### BACKGROUND

As an important display technology, the ultra-high-resolution display technology can improve the display effect of the display screen and can be applied to a variety of special display products. Currently, in the case where the ultra-high-resolution display technology is applied to a 3D display product, how to optimize a design through a pixel structure to achieve a good 3D display effect has become an important research direction.

### SUMMARY

At least one embodiment of the present disclosure provides a display substrate and a manufacturing method thereof, and a display device.

At least one embodiment of the present disclosure provides a display substrate, including: a base substrate, an insulating layer, a conductive layer and a plurality of second transmission portions; the insulating layer is located on the base substrate; the conductive layer is located on a side of the insulating layer, the conductive layer includes a plurality of first transmission portions arranged in a first direction; the plurality of second transmission portions are located on a side of the insulating layer away from the conductive layer, at least one first transmission portion extends in a second direction, a plurality of connection via holes are provided in the insulating layer, and the at least one first transmission portion is electrically connected with at least one second transmission portion through at least one connection via hole; an orthographic projection of at least a portion of at least one edge of the at least one first transmission portion extending in the second direction on the base substrate falls into an orthographic projection of the connection via hole on the base substrate, the second direction intersects with the first direction.

For example, according to the display substrate provided by the present disclosure, a material of the first transmission portion is different from a material of the second transmission portion.

For example, according to the display substrate provided by the present disclosure, an area of an orthographic projection of an overlapping portion of the first transmission portion and the second transmission portion in the connection via hole on the base substrate is 0.3 to 0.8 of an area of the orthographic projection of the connection via hole on the base substrate.

For example, according to the display substrate provided by the present disclosure, the display substrate further includes a plurality of sub-pixels located on the base substrate, each of at least part of the plurality of sub-pixels includes a light-emitting element and a pixel circuit, and the light-emitting element includes a light-emitting functional layer and a first electrode and a second electrode located on both sides of the light-emitting functional layer in a direction perpendicular to the base substrate, the first electrode is located between the light-emitting functional layer and the base substrate, the pixel circuit includes a plurality of transistors, and the first electrode of the light-emitting element is electrically connected with the plurality of transistors.

For example, according to the display substrate provided by the present disclosure, the pixel circuit includes an active semiconductor layer, the active semiconductor layer includes a channel region and a source and drain regions of each of the plurality of transistors, and the active semiconductor layer is located between the conductive layer and the base substrate, the plurality of second transmission portions include at least one first sub-transmission portion located in the active semiconductor layer, and the insulating layer includes a first insulating layer located between the conductive layer and the at least one first sub-transmission portion, the plurality of connection via holes include a first connection via hole located in the first insulating layer, the plurality of first transmission portions include a first type transmission portion, the first type transmission portion is connected with the first sub-transmission portion through the first connection via hole.

For example, according to the display substrate provided by the present disclosure, the at least one first sub-transmission portion includes a first sub-transmission portion extending in the second direction, an orthographic projection of at least a portion of two opposite edges of the first sub-transmission portion extending in the second direction on the base substrate falls into an orthographic projection of the first connection via hole on the base substrate, and an orthographic projection of at least a portion of two opposite edges of the first type transmission portion extending in the second direction on the base substrate falls into the orthographic projection of the first connection via hole on the base substrate.

For example, according to the display substrate provided by the present disclosure, the first type transmission portion includes an edge extending in the first direction, an orthographic projection of at least a portion of the edge extending in the first direction on the base substrate falls into an orthographic projection of the first connection via hole on the base substrate.

For example, according to the display substrate provided by the present disclosure, the first sub-transmitting portion extending in the second direction includes an edge extending in the first direction, an orthographic projection of at least a portion of the edge extending in the first direction on the base substrate falls into the orthographic projection of the first connection via hole on the base substrate.

For example, according to the display substrate provided by the present disclosure, the at least one first sub-transmission portion includes a first sub-transmission portion extending in the first direction, an orthographic projection of at least a portion of an edge of the first sub-transmission portion extending in the first direction on the base substrate falls into an orthographic projection of the first connection via hole on the base substrate, and an orthographic projection of at least a portion of two opposite edges of the first type transmission portion extending in the second direction on the base substrate falls into the orthographic projection of the first connection via hole on the base substrate.

For example, according to the display substrate provided by the present disclosure, the pixel circuit includes an active semiconductor layer, the active semiconductor layer includes a channel region and a source and drain regions of each of the plurality of transistors, and the active semiconductor layer is located between the conductive layer and the base substrate, the plurality of second transmission portions include at least one second sub-transmission portion located between the conductive layer and the active semiconductor layer, and the insulating layer includes a second insulating layer located between the plurality of first transmission portions and the at least one second sub-transmission portion, the plurality of first transmission portions includes a second type transmission portion, the plurality of connection via holes includes a second connection via hole located in the second insulating layer, and the second type transmission portion is connected with the second sub-transmission portion through the second connection via hole.

For example, according to the display substrate provided by the present disclosure, an orthographic projection of at least a portion of two opposite edges of the second type transmission portion extending in the second direction on the base substrate falls into an orthographic projection of the second connection via hole on the base substrate, an orthographic projection of at least a portion of two opposite edges of the second sub-transmission portion extending in the second direction on the base substrate falls into the orthographic projection of the second connection via hole on the base substrate.

For example, according to the display substrate provided by the present disclosure, a maximum size of the connection via hole in the second direction is larger than a maximum size of the connection via hole in the first direction.

For example, according to the display substrate provided by the present disclosure, the display substrate further includes a first adjacent transmission portion and a second adjacent transmission portion that are adjacent to and arranged at intervals with the first transmission portion in the first direction, the first adjacent transmission portion being closer to the first transmission portion than the second adjacent transmission portion, the first transmission portion includes a first edge close to the first adjacent transmission portion and a second edge close to the second adjacent transmission portion, and both the first edge and the second edge extend in the second direction, and an area of an orthographic projection of a portion of the first edge that falls into the connection via hole on the base substrate is larger than an orthographic projection of a portion of the second edge that falls into the connection via hole on the base substrate.

For example, according to the display substrate provided by the present disclosure, the plurality of second transmission portions include at least one third sub-transmission portion located on a side of the conductive layer away from the base substrate, and the third sub-transmission portion is located between the first electrode and the conductive layer, the insulating layer includes a third insulating layer and a fourth insulating layer that are located between the plurality of first transmission portions and the at least one third sub-transmission portion, the third insulating layer is located between the fourth insulating layer and the base substrate, the plurality of connection via holes include a third connection via hole located in the third insulating layer and a fourth connection via hole located in the fourth insulating layer, the third connection via hole is communicated with the fourth connection via hole, and an inner diameter of the third connection via hole is smaller than an inner diameter of the fourth connection via hole, the plurality of first transmission portions include a third type transmission portion, the third type transmission portion is connected with the third sub-transmission portion through the third connection via hole and the fourth connection via hole.

For example, according to the display substrate provided by the present disclosure, an orthographic projection of at least a portion of two opposite edges of the third type transmission portion extending in the second direction on the base substrate falls into an orthographic projection of the fourth connection via hole on the base substrate.

For example, according to the display substrate provided by the present disclosure, the third sub-transmission portion extends in the first direction, and the orthographic projection of the fourth connection via hole on the base substrate falls into an orthographic projection of the third sub-transmission portion on the base substrate.

For example, according to the display substrate provided by the present disclosure, an area of an orthographic projection of a portion of the third type transmission portion located in the fourth connection via hole on the base substrate is larger than an area of an orthographic projection of a portion of the first type transmission portion located in the first connection via hole on the base substrate.

For example, according to the display substrate provided by the present disclosure, an orthographic projection of another third type transmission portion adjacent to and arranged at intervals with the third type transmission portion on the base substrate falls into the orthographic projection of the fourth insulating layer on the base substrate.

For example, according to the display substrate provided by the present disclosure, the display substrate further includes: an anode insulating layer, located between the first electrode and the third sub-transmission portion, the anode insulating layer includes an anode connection via hole, the first electrode is connected with the third sub-transmission portion through the anode connection via hole, an orthographic projection of the anode connection via hole on the base substrate does not overlap with an orthographic projection of the fourth connection via hole on the base substrate, orthographic projections of at least a portion of the edge of the third type transmission portion extending in the second direction and away from the anode connection via hole and at least a portion of the edge of the third type transmission portion extending in the first direction on the base substrate fall into an orthographic projection of the third connection via hole on the base substrate.

At least one embodiment of the present disclosure further provides a display device, including the display substrate according to any one of claims 1-19.

For example, according to the display device provided by at least one embodiment of the present disclosure, the display device further includes: a plurality of sub-pixels and a light-splitting structure, the plurality of sub-pixels are located on the base substrate, the light-splitting structure is arranged on a light exiting side of the display substrate, and the light-splitting structure is configured to direct the light emitted by the plurality of sub-pixels to different viewpoint regions, the light-splitting structure includes a plurality of light-splitting portions extending in the first direction and arranged in the second direction, and each of the plurality of the light-splitting portions includes a lens.

At least one embodiment of the present disclosure further provides a manufacturing method of a display substrate, including: forming an insulating layer, a conductive layer and a plurality of second transmission portions on a base substrate, the conductive layer being located on a side of the insulating layer, the plurality of second transmission portions being located on a side of the insulating layer away from the conductive layer; forming the conductive layer includes forming a first transmission layer, and patterning the first transmission layer to form a first pattern, and the first pattern includes a plurality of first transmission portions; forming the insulating layer includes patterning the insulating layer, so that the insulating layer includes at least one connection via hole; forming the plurality of second transmission portions includes forming a second transmission layer and patterning the second transmission layer to form a second pattern, and the second pattern includes the plurality of second transmission portions; the at least one first transmission portion is electrically connected with at least one second transmission portion through at least one connection via hole, an orthographic projection of a portion of an edge of the at least one first transmission portion extending in the second direction on the base substrate falls into an orthographic projection of the connection via hole on the base substrate, the second direction intersects with the first direction.

For example, according to the manufacturing method of the display substrate provided by the present disclosure, a portion of an edge of the at least one first transmission portion extending in the second direction on the base substrate falling into an orthographic projection of the connection via hole on the base substrate includes:
a distance between a portion of an edge of the at least one first transmission portion extending in the second direction and the first connection via hole is set as Space, and the Space satisfies: Space≤\sqrt{K1*OL1²+K1*OL2²+Tor1²+Tor2²}+Bias1+Bias2, OL1 refers to a minimum spacing between a line in the first transmission layer and a corresponding design position, OL2 refers to a minimum spacing between a line in the second transmission layer and a corresponding design position, Tor1 refers to a uniformity of the first pattern, Tor2 refers to a uniformity of the second pattern, Bias1 refers to a size accuracy of the first pattern, and Bias2 refers to a size accuracy of the second pattern.

### BRIEF DESCRIPTION OF DRAWINGS

In order to more clearly illustrate the technical solutions of the embodiments of the present disclosure, the drawings of the embodiments will be briefly described in the following, it is obvious that the described drawings below are only related to some embodiments of the present disclosure and thus are not limitative to the present disclosure.

FIG. 1 is a plan view of stacked layers of a display substrate provided by at least one embodiment of the present disclosure.

FIG. 2 is a schematic cross-sectional view of a display substrate provided by at least one embodiment of the present disclosure.

FIG. 3 illustrates a partial structural diagram corresponding to a first connection via hole 511 in FIG. 1.

FIG. 4 is a schematic cross-sectional view along line A1-A1′ in FIG. 3.

FIG. 5 is a schematic cross-sectional view of the partial structure of the display substrate illustrated in FIG. 3 along line B1-B1′.

FIG. 6 illustrates a partial structural diagram corresponding to a first connection via hole 512 in FIG. 1.

FIG. 7 is a schematic cross-sectional view of the partial structure of the display substrate illustrated in FIG. 6 along line B2-B2′.

FIG. 8 illustrates a partial structural diagram corresponding to a first connection via hole 513 in FIG. 1.

FIG. 9 is a schematic cross-sectional view of the partial structure of the display substrate illustrated in FIG. 8 along line B3-B3′.

FIG. 10 is a schematic cross-sectional view of the partial structure of the display substrate illustrated in FIG. 8 along line A3-A3′.

FIG. 11 illustrates a partial structural diagram corresponding to a first connection via hole 514 in FIG. 1.

FIG. 12 is a schematic cross-sectional view of the partial structure of the display substrate illustrated in FIG. 11 along line B4-B4′.

FIG. 13 is a schematic cross-sectional view of the partial structure of the display substrate illustrated in FIG. 11 along line A4-A4′.

FIG. 14 illustrates a partial structural diagram corresponding to a second connection via hole 521 in FIG. 1.

FIG. 15 is a schematic cross-sectional view of the partial structure of the display substrate illustrated in FIG. 14 along line B5-B5′.

FIG. 16 is a schematic cross-sectional view of the partial structure of the display substrate illustrated in FIG. 14 along line A5-A5′.

FIG. 17 illustrates a partial structural diagram corresponding to a third connection via hole 531 and a fourth connection via hole 532 in FIG. 1.

FIG. 18 is a schematic cross-sectional view of the partial structure of the display substrate illustrated in FIG. 17 along line B6-B6′.

FIG. 19 is a schematic cross-sectional view of the partial structure of the display substrate illustrated in FIG. 17 along line A6-A6′.

FIG. 20 illustrates a partial structural diagram corresponding to an anode connection via hole 54 and a fourth connection via hole 5321 in FIG. 1.

FIG. 21 is a schematic cross-sectional view of the partial structure of the display substrate illustrated in FIG. 20 along line B7-B7′.

FIG. 22 is a schematic cross-sectional view of the partial structure of the display substrate illustrated in FIG. 20 along line A7-A7′.

FIG. 23 is a schematic diagram of a pixel circuit corresponding to a display substrate provided by at least one embodiment of the present disclosure.

FIG. 24 illustrates a partial structural diagram corresponding to the first connection via hole 511 in FIG. 1 in another embodiment of the present disclosure.

FIG. 25A is a schematic diagram of a display device provided by an embodiment of the present disclosure.

FIG. 25B is a schematic diagram of another display device provided by an embodiment of the present disclosure.

FIG. 26 to FIG. 31 are schematic flow diagrams of a manufacturing method of the display substrate provided by at least one embodiment of the present disclosure.

### DETAILED DESCRIPTION

In order to make objectives, technical details and advantages of the embodiments of the present disclosure more clearly, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects.

The features such as “vertical”, “parallel” and “same” used in the embodiments of the present disclosure all include features such as “vertical”, “parallel” and “same” in a strict sense, as well as cases where “approximately vertical”, “approximately parallel” and “approximately same” contain certain errors, considering the measurement and the errors related to the measurement of a specific quantity (that is, limitations of measurement system), the wording of approximately is within the acceptable deviation range for a specific value determined by a person of ordinary skill in the art. The “center” in the embodiment of the present disclosure may include a strictly geometric center position and a roughly central position in a small area around the geometric center.

Generally, a 3D display product usually includes a plurality of viewpoints, each viewpoint is configured to display different object information, and with micro lenses, a 3D display effect can be achieved. For the 3D display product, in the case where the number of viewpoints is greater, the resolution of the 3D display product is higher, so that the 3D display effect is better. However, as the number of the viewpoints in the 3D display product continues to increase, the pixel arrangement space in the 3D display product is getting tighter, therefore, how to achieve an orderly distribution of a plurality of sub-pixels in a limited layout space has become an urgent problem that needs to overcome.

During the research, the inventor(s) of this application found that: in the 3D display product, the pixel circuit of a sub-pixel is usually provided with connection via holes for connecting conductive structures arranged in different layers. Usually, the conductive structures include a first portion located in the connection via hole and a second portion located outside the connection via hole and surrounding the connection via hole in the circumferential direction, that is to say, an orthographic projection of the connection via hole on the base substrate of the 3D display product usually completely falls into an orthographic projection of the conductive structure on the base substrate, in this design manner, the electrical connection between conductive structures located in different layers is mainly achieved through the first portion of the conductive structure, while the second portion of the conductive structure located outside the connection via hole is usually unnecessary, and this portion of the conductive structure will further occupy too much layout space in the layer where the conductive structure is located, which is not conducive to the layout design, affects the resolution of the 3D display product, causes a risk of signal crosstalk between different conductive structures at the same time, and leads to poor display and other phenomena.

At least one embodiment of the present disclosure provides a display substrate, including a base substrate, an insulating layer, a conductive layer and a plurality of second transmission portions, the insulating layer is located on the base substrate; the conductive layer is located on a side of the insulating layer, the conductive layer comprising a plurality of first transmission portions arranged in a first direction; the plurality of second transmission portions are located on a side of the insulating layer away from the conductive layer; at least one first transmission portion extends in a second direction, a plurality of connection via holes are provided in the insulating layer, and the at least one first transmission portion is electrically connected with at least one second transmission portion through at least one connection via hole; an orthographic projection of at least a portion of an edge of the at least one first transmission portion extending in the second direction on the base substrate falls into an orthographic projection of the connection via hole on the base substrate, the second direction intersects with the first direction.

The display substrate provided by the embodiment of the present disclosure can reduce a coverage area of the first transmission portion outside the edge of the connection via hole and reduce the space occupied by the first transmission portion in the first direction by locating at least a portion of the edge of the first transmission portion extending in the second direction in the connection via hole, which facilitates the layout arrangement and improves the display effect.

The display substrate and a manufacturing method thereof, and a display device provided by the embodiments of the present disclosure will be described below with reference to the accompanying drawings.

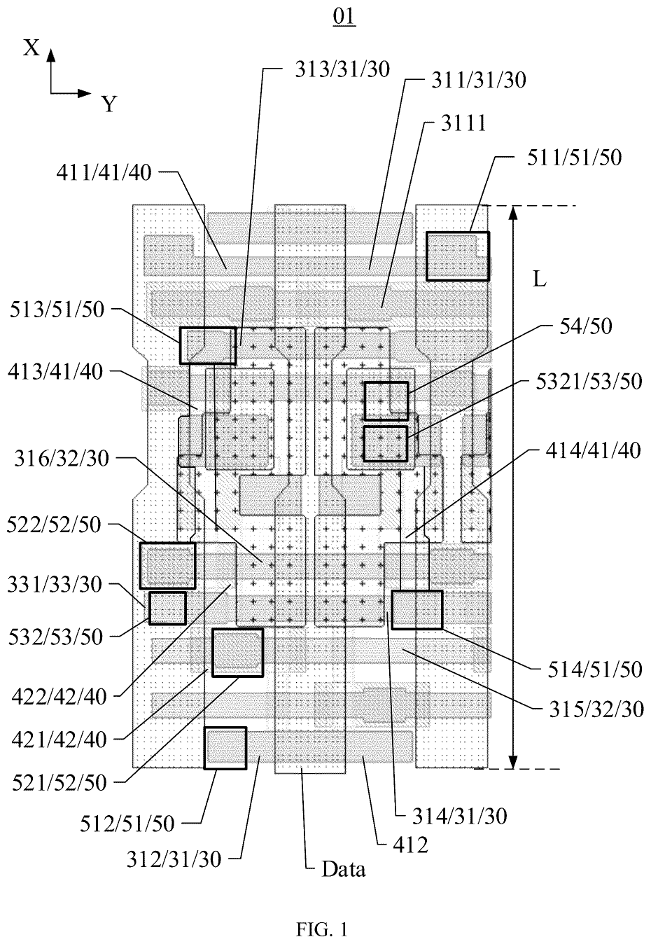

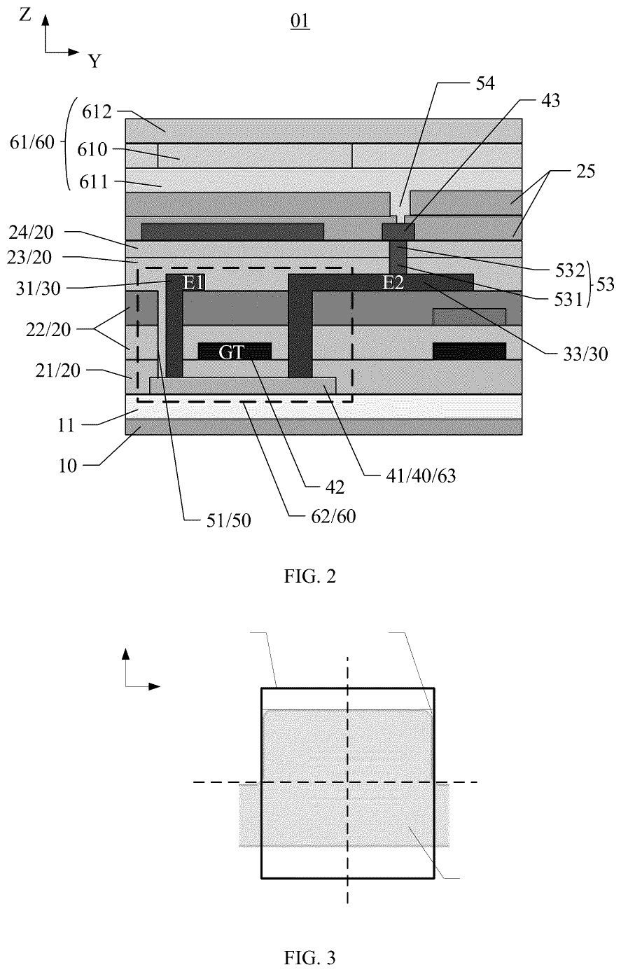

FIG. 1 is a plan view of stacked layers of a display substrate provided by at least one embodiment of the present disclosure; FIG. 2 is a schematic cross-sectional view of a display substrate provided by at least one embodiment of the present disclosure.

As illustrated in FIG. 1 and FIG. 2, the display substrate 01 includes abase substrate 10, an insulating layer 20, a conductive layer 30 and a plurality of second transmission portions 40, the insulating layer 20 is located on the base substrate 10. The conductive layer 30 is located on a side of the insulating layer 20, and the conductive layer 30 includes a plurality of first transmission portions 31 arranged in the first direction X.

As illustrated in FIG. 2, the plurality of second transmission portions 40 are located on a side of the insulating layer 20 away from the conductive layer 30. For example, the plurality of second transmission portions 40 may be located in the same layer or in different layers. For example, the insulating layer 20 may be located between the second transmission portion 40 and the conductive layer 30 and in contact with the second transmission portion 40 and the conductive layer 30 respectively, but is not limited thereto.

As illustrated in FIG. 1 and FIG. 2, at least one first transmission portion 31 extends in the second direction Y, a plurality of connection via holes 50 are provided in the insulating layer 20, and at least one first transmission portion 31 passes through at least one connection via hole 50 to be electrically connected with at least one second transmission portion 40. For example, one first transmission portion 31 can be electrically connected with one second transmission portion 40 through one connection via hole 50, or one first transmission portion 31 can be electrically connected with the same second transmission portion through two or more connection via holes 50, or one first transmission portion 31 can be electrically connected with two or more second transmission portions 40 through at least one connection via hole 50.

As illustrated in FIG. 1 and FIG. 2, an orthographic projection of a portion of an edge of at least one first transmission portion 31 extending in the second direction Y on the base substrate 10 falls into an orthographic projection of the connection via hole 50 on the base substrate 10. For example, the first transmission portion 31 is in contact with the second transmission portion 40 through a portion located in the connection via hole 50 to perform electrical connection. In the second direction Y, a size of the portion of the first transmission portion 31 located in the connection via hole 50 is smaller than a size of the connection via hole 50, so that an occupied area of the first transmission portion 31 in the first direction X can be reduced, which is conducive to saving the layout space. The second direction Y intersects with the first direction X. For example, the first direction X may be perpendicular to the second direction Y.

For example, in some embodiments of the present disclosure, in the first direction X, a size of a portion of the first transmission portion 31 extending in the second direction Y and not overlapping with the connection via hole 50 may also be smaller than the size of the connection via hole 50, thereby reducing the size of the first transmission portion 31 as a whole to save the layout space.

The display substrate provided by the embodiment of the present disclosure can reduce a coverage area of the first transmission portion outside the edge of the connection via hole and reduce the space occupied by the first transmission portion in the first direction by locating at least a portion of the edge of the first transmission portion extending in the second direction in the connection via hole, which facilitates the layout arrangement and improves the display effect.

For example, as illustrated in FIG. 1 and FIG. 2, the first transmission portion 31 and the second transmission portion 40 include conductive materials, such as metal materials, but are not limited thereto. For example, the material of the first transmission portion 31 is different from the material of the second transmission portion 40. For example, the first transmission portion 31 may adopt a composite material composed of Ti/Al/Ti stacked in sequence, but is not limited thereto. For example, in the case of forming the first transmission portion 31, a size of a portion where the material configured to form the first transmission portion 31 overlapping with the edge of the connection via hole 50 can be set to a specific design value, processes such as exposure, development, etching, etc. will cause the size of the material to change, for example, it may cause the edge portion with the specific design value to eventually shrink into the connection via hole 50 (this portion involves the manufacturing method of the display substrate, please refer to the embodiments described in detail later). At the same time, in order to enable the edge portion with the specific design value to eventually shrink into the connection via hole 50, the range of the above design value is generally small, for example, it can be 1 μm to 1.2 μm, but is not limited to this, therefore, by making the material of the first transmission portion 31 different from the material of the second transmission portion 40, an impact on the previously produced film layer (such as the second transmission portion 40 or the first transmission portion 31) by a film layer produced later (such as the first transmission portion 31 or the second transmission portion 40) can be reduced during the manufacturing process (for example, during etching), so as to reduce a risk of damage to the previously produced film layer.

For example, as illustrated in FIG. 1 and FIG. 2, the material of the first transmission portion 31 may have an etching selectivity ratio different from that of the material of the second transmission portion 40, so that in the process of patterning the conductive layer 30 by the etching solution to form the first transmission portion 31, a risk of etching the second transmission portion 40 or other film layers by the etching solution can be reduced.

For example, as illustrated in FIG. 1 and FIG. 2, in order to ensure that the first transmission portion 31 can be effectively electrically connected with the second transmission portion 40 in the connection via hole 50, in the connection via hole 50, the first transmission portion 31 and the second transmission portion 40 need to have a sufficient contacting area to ensure normal transmission of electrical signals. For example, an area of the orthographic projection of an overlapping portion of the first transmission portion 31 and the second transmission portion 40 in the connection via hole 50 on the base substrate 10 is 0.3 to 0.8 of an area of the orthographic projection of the connection via hole 50 on the base substrate 10, but is not limited to this. For example, the above size can be at least one of 0.3 to 0.5, 0.4 to 0.7, 0.5 to 0.8, and 0.35 to 0.65 and 0.25 to 0.75, which can be specifically set according to design requirements, and is not limited in the embodiments of the present disclosure.

For example, as illustrated in FIG. 1 and FIG. 2, the display substrate 01 further includes a plurality of sub-pixels 60 located on the base substrate 10, and each of at least some of the sub-pixels 60 includes a light-emitting element 61 and a pixel circuit 62, the light-emitting element 61 includes a light-emitting functional layer 610, and a first electrode 611 and a second electrode 612 that are located on both sides of the light-emitting functional layer 610 in a direction perpendicular to the base substrate 10, the first electrode 611 is located between the light-emitting functional layer 610 and the base substrate 10. For example, the direction perpendicular to the base substrate 10 may be a third direction Z. For example, the third direction Z is perpendicular to the above-mentioned first direction X, and the third direction Z is perpendicular to the second direction Y, but is not limited thereto.

For example, as illustrated in FIG. 2, the pixel circuit 62 may include a plurality of transistors, and the first electrode 611 of the light-emitting element 61 is electrically connected with one of the plurality of transistors (for example, a driving transistor), so that the pixel circuit 62 can drive the light-emitting element 61 to emit light. For example, the pixel circuit 62 is configured to provide driving current to drive the light-emitting element 61 to emit light. For example, the light-emitting element 61 is an organic light-emitting diode (OLED), a micron light-emitting diode (Micro LED), or a quantum dot light-emitting diode (QLED), the light-emitting element 61 emits red light, green light, blue light or white light, etc. under the driving of its corresponding pixel circuit 62. For example, the plurality of sub-pixels 60 may include a plurality of first type sub-pixels, a plurality of second type sub-pixels, and a plurality of third type sub-pixels, which are configured to emit light of different colors, such as red, green, blue, etc. For example, one of the first type sub-pixel and the second type sub-pixel is a blue sub-pixel that emits blue light, the other is a red sub-pixel that emits red light, and the third type sub-pixel is a green sub-pixel that emits green light. For example, the first type sub-pixel is a blue sub-pixel, the second type sub-pixel is a red sub-pixel, and an area of a light-emitting region of the blue sub-pixel is larger than an area of the light-emitting region of the red sub-pixel. For example, an area of the light-emitting region of the blue sub-pixel is larger than the area of the light-emitting region of the green sub-pixel. Of course, the embodiments of the present disclosure are not limited thereto. For example, the sub-pixels 60 may be arranged in different forms according to actual layout design requirements, for example, “diamond arrangement”, “diamond-like arrangement”, “GGRB arrangement”, etc., which are not limited in the embodiments of the present disclosure.

For example, as illustrated in FIG. 1 and FIG. 2, an orthographic projection of the pixel circuit 62 of the sub-pixel 60 of each color on the base substrate 10 is generally located in a rectangular region, and a size L of each rectangular region in the first direction X is 55 μm to 60 μm, and each rectangular region in at least some of the rectangular regions is provided with 8 to 15 first transmission portions 31. For example, for the display substrate 01 illustrated in FIG. 1, the size L of each rectangular region in the first direction X is related to a size of the display substrate 01 and satisfies the following formula:

$$\begin{matrix}( W \times b \times N ) \hat{} 2 + ( L \times 3 \times M ) \hat{} 2 = a \hat{} 2 \\ ( W \times b \times N ) / ( L \times 3 \times M ) = c / d\end{matrix}$$

In the formula, L refers to a height (μm) of the viewpoint in the sub-pixel, W refers to a width (μm) of the viewpoint in the sub-pixel, a (inch) refers to a size of the display substrate along its diagonal, b refers to a number of viewpoints in the sub-pixel, c/d refers to a width-to-length ratio of the display substrate, M refers to a number of rows of sub-pixels in the display substrate, and N refers to a number of columns of sub-pixels in the display substrate. For example, for the display substrate 01 illustrated in FIG. 1, a can be 30 inches, M can be 3840, N can be 2160, c/d can be 16/9, b can be 11, and W can be 15.8 μm to 16 μm, but are not limited thereto. For example, the above L may be at least one of 57 μm to 58 μm and 57.5 μm to 59.5 μm, but is not limited thereto.

As can be seen from FIG. 1, in the rectangular region corresponding to the orthographic projection of the pixel circuit 62 of each sub-pixel 60, the first transmission portions 31 basically extend in the second direction Y, and the plurality of first transmission portions 31 are arranged in the first direction X, and a certain distance is provided between adjacent first transmission portions 31, the display substrate provided by the embodiment of the present disclosure can reduce a coverage area of the first transmission portion 31 outside the edge of the connection via hole and reduce the space occupied by the first transmission portion 31 in the first direction X by locating at least a portion of the edge of the first transmission portion 31 extending in the second direction Y in the connection via hole 50, so as to adapt to layout arrangement requirements in the layout design with high pixel density.

For example, the layout setting method illustrated in FIG. 1 can be used for ultra-high-resolution display products, but is not limited thereto. For example, the number of the first transmission portions 31 in each of the above rectangular regions can be at least one of 8 to 12, 9 to 13, and 10 to 14, but is not limited thereto, which can be set according to design requirements.

For example, as illustrated in FIG. 2, the insulating layer 20 of the display substrate 01 includes a first insulating layer 21, a second insulating layer 22, a third insulating layer 23, a fourth insulating layer 24 and an anode insulating layer 25, the display substrate 01 further includes a buffer layer 11, and the buffer layer 11, the first insulating layer 21, the second insulating layer 22, the third insulating layer 23, the fourth insulating layer 24 and the anode insulating layer 25 are arranged in sequence in the direction perpendicular to the base substrate 10. For example, the second insulating layer 22 may also be called a gate insulating layer, and the third insulating layer 23 may also be called an interlayer insulating layer, but is not limited thereto. The pixel circuit 62 includes an active semiconductor layer 63 located on the buffer layer 11, the active semiconductor layer 63 includes the channel region and the source and drain regions of each transistor, the active semiconductor layer 63 is located between the conductive layer 30 and the base substrate 10. As illustrated in FIG. 2, the active semiconductor layer 63 is located between the second insulating layer 22 and the buffer layer 11. For example, portions of the active semiconductor layer 63 in the source and drain regions are electrically connected with the source electrode E1 and the drain electrode E2, respectively, the source electrode E1 and the drain electrode E2 are covered by the third insulating layer 23, and both of the source electrode E1 and the drain electrode E2 are connected with the active semiconductor layer 63, respectively, a gate electrode GT is provided on the first insulating layer 21, and the drain electrode E2 is electrically connected with the first electrode 611 of the light-emitting element 61 through a via hole penetrating the third insulating layer 23, the fourth insulating layer 24 and the anode insulating layer 25. For example, the active semiconductor layer 63 may adopt low temperature poly-silicon (LTPS), but is not limited thereto.

For example, as illustrated in FIG. 2, the first transmission portion 30 is located in the third insulating layer 23. The plurality of second transmission portions 40 in the display substrate 01 include at least one first sub-transmission portion 41 located in the active semiconductor layer 63, and the first insulating layer 21 is located between the conductive layer 30 and the at least one first sub-transmission portion 41, the plurality of connection via holes 50 in the display substrate 01 include a first connection via hole 51 located in the first insulating layer 21, and the plurality of first transmission portions 30 in the display substrate 01 include a first type transmission portion 31, the first type transmission portion 31 is connected with the first sub-transmission portion 41 through the first connection via hole 51. For example, the first sub-transmission portion 41 may be the source electrode or drain electrode of a transistor in the display substrate 01, and the first type transmission portion 31 may be a portion of a signal line. After the first type transmission portion 31 is connected with the first sub-transmission portion 41 through the first connection via hole 51, it can perform electrical signal transmission with the first sub-transmission portion 41, but is not limited thereto. For example, the first insulating layer 21 may be some insulating layers, or all insulating layers between the first sub-transmission portion 41 and the first transmission portion 30, which is not limited in the embodiments of the present disclosure.

For example, as illustrated in FIG. 1 and FIG. 2, at least one first sub-transmission portion 41 in the active semiconductor layer 63 may include a plurality of first sub-transmission portions 41, and the plurality of first sub-transmission portions 41 may have different shapes and different extension directions. For example, the plurality of first sub-transmission portions 41 may be configured to be electrically connected with different signal lines to transmit different electrical signals. For example, a first insulating layer 21 and a second insulating layer 22 are provided between the first sub-transmission portion 41 and the first type transmission portion 31. For example, the second insulating layer 22 may be an insulating layer at a side of the first insulating layer 21 away from the base substrate 10, or may be an insulating layer in the first insulating layer 21, which is not limited in the embodiments of the present disclosure.

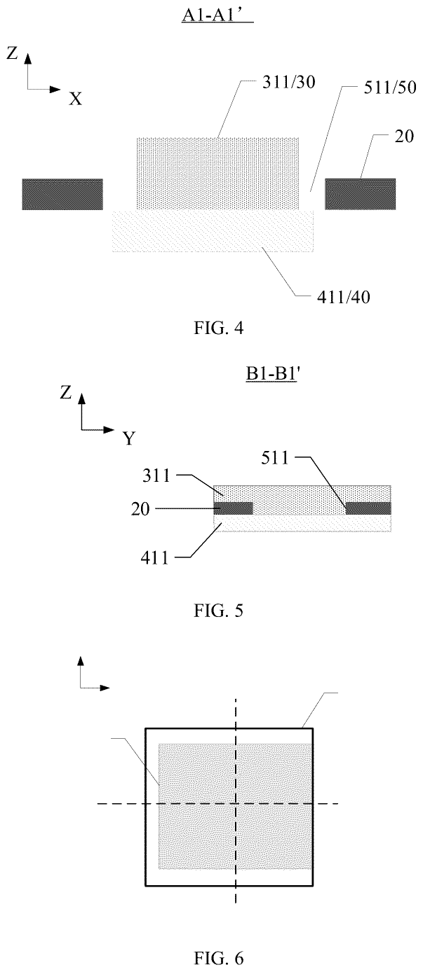

For example, as illustrated in FIG. 1, at least one first sub-transmission portion 41 located in the active semiconductor layer 63 includes a first sub-transmission portion 411 extending in the second direction Y, and the plurality of first type transmission portions 31 includes a first type transmission portion 311 extending in the second direction Y, the first connection via hole 51 located in the first insulating layer 21 of the display substrate 01 includes a first connection via hole 511 to electrically connect the first sub-transmission portion 411 and the first type transmission portion 311. For example, in FIG. 1, the first type transmission portion 311 and the first sub-transmission portion 411 can be a stacked structure, and the first type transmission portion 311 covers the first sub-transmission portion 411. For example, for the sake of clarity, FIG. 3 illustrates a schematic partial structural diagram corresponding to the first connection via hole 511 in FIG. 1; FIG. 4 is a schematic cross-sectional view along line A1-A1′ in FIG. 3; FIG. 5 is a schematic cross-sectional view of the partial structure of the display substrate illustrated in FIG. 3 along line B1-B1′.

For example, as illustrated in FIG. 1, FIG. 3 and FIG. 4, the line A1-A1′ extends in the first direction X, and signal transmission directions of the first type transmission portion 311 and the first sub-transmission portion 411 are both perpendicular to the first direction X. An orthographic projection of at least a portion of the two opposite edges of the first sub-transmission portion 411 extending in the second direction Y on the base substrate falls into an orthographic projection of the first connection via hole 511 on the base substrate, and an orthographic projection of at least a portion of the two opposite edges of the first type transmission portion 311 extending in the second direction Y on the base substrate also falls into the orthographic projection of the first connection via hole 511 on the base substrate.

For example, as illustrated in FIG. 1, FIG. 3 and FIG. 4, in the first direction X, a size of the portion of the first type transmission portion 311 located in the first connection via hole 511 is smaller than a size of the first connection via hole 511, a size of the portion of the first sub-transmission portion 411 located in the first connection via hole 511 is also smaller than the size of the first connection via hole 511. For example, at least a portion of each of the opposite edges of the first type transmission portion 311 extending in the second direction Y is located in the first connection via hole 511, and at least a portion of each of the opposite edges of the first sub-transmission portion 411 extending in the second direction Y is located in the first connection via hole 511, so that sizes of the portions of the first type transmission portion 311 and the first sub-transmission portion 411 that respectively overlap with the first connection via hole 511 can be reduced, so as to reduce the layout areas occupied by the first type transmission portion 311 and the first sub-transmission portion 411 and save the layout space.

For example, as illustrated in FIG. 1 and FIG. 3, the extension directions of the first sub-transmission portion 411 and the first type transmission portion 311 are the same, and the orthographic projection of the first sub-transmission portion 411 on the base substrate is basically coincident with the orthographic projection of the first type transmission portion 311 on the base substrate. Therefore, it can be seen from FIG. 1 that both of the signal transmission direction of the first sub-transmission portion 411 and the signal transmission direction of the first type transmission portion 311 are the second direction Y.

For example, as illustrated in FIG. 1 and FIG. 4, a portion of the two opposite edges extending in the second direction Y of the first type transmission portion 311 is located in the connection via hole 50, but the embodiments of the present disclosure are not limited thereto. For example, a portion of one edge of the first type transmission portion 311 extending in the second direction Y is located in the connection via hole 50, and another edge extending in the second direction Y of the first type transmission portion 311 is located outside the connection via hole 50 to adapt to different design requirements, which are not limited in the embodiments of the present disclosure.

For example, with reference to FIG. 5, it can be seen that in the second direction Y, the size of the first connection via hole 511 is smaller than the size of the first type transmission portion 311, and the size of the first connection via hole 511 is smaller than the size of the first sub-transmission portion 411. Each of the first type transmission portion 311 and the first sub-transmission portion 411 includes a portion located in the first connection via hole 511 and a portion that overlaps with the edge of the first connection via hole 511 and extends in the second direction Y. The size of the portion of each of the first type transmission portion 311 and the first sub-transmission portion 411 located in the first connection via hole 511 in the second direction Y is equal to the size of the first connection via hole 511 in the second direction Y. Therefore, in the second direction Y, the size of the portion where the first type transmission portion 311 and the first sub-transmission portion 411 are in contact with each other is equal to the size of the first connection via hole 511 in the second direction Y, so that the first type transmission portion 311 and the first sub-transmission portion 411 can perform good signal transmission in the signal transmission direction.

For example, as illustrated in FIG. 1 and FIG. 3, in the first direction X, the size of the portion of the first type transmission portion 311 located outside the first connection via hole 511 and located on both sides of the first connection via hole 511 in the second direction Y may not be larger than the size of the first connection via hole 511, for example, it may be equal to the size of the first connection via hole 511, or smaller than the size of the first connection via hole 511, but is not limited thereto. For example, the size of the portion of the first type transmission portion 311 located outside the first connection via hole 511 and located on both sides of the first connection via hole 511 in the second direction Y may be the same, or substantially the same as the size of the portion of the first type transmission portion 311 located in the first connection via hole 511, which is beneficial to reducing the size of the first type transmission portion 311 in the first direction X as a whole. Similarly, the size of the portion of the first sub-transmission portion 411 located outside the first connection via hole 511 and located on both sides of the first connection via hole 511 in the second direction Y can also be the same, or substantially the same as the size of the portion of the first sub-transmission portion 411 located in the first connection via holes 511, which is beneficial to saving layout space. In the direction from the signal transmission upstream to the signal transmission downstream of the first type transmission portion 311, the first type transmission portion 311 is continuously arranged, and the size of the first type transmission portion 311 in this direction is equal to the size of the first connection via hole 511 in this direction, so that the first type transmission portion 311 can perform effective signal transmission.

For example, as illustrated in FIG. 2 and FIG. 4, the portion of the first connection via hole 511 where the first type transmission portion 311 is not arranged may be filled with the third insulating layer 23, but is not limited thereto.

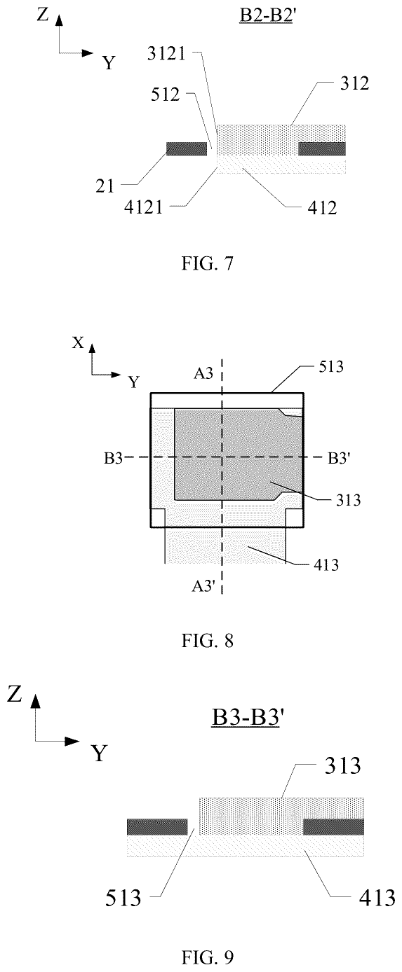

For example, as illustrated in FIG. 1 and FIG. 2, at least one first sub-transmission portion 41 located in the active semiconductor layer 63 may further include a first sub-transmission portion 412 extending in the second direction Y, a plurality of first type transmission portion 31 may include a first type transmission portion 312 extending in the second direction Y, and the first connection via hole 51 located in the first insulating layer 21 includes a first connection via hole 512 which electrically connects the first sub-transmission portion 412 with the first type transmission portion 312. For example, in FIG. 1, the first type transmission portion 312 and the first sub-transmission portion 412 form a stacked structure, and the first type transmission portion 312 covers the first sub-transmission portion 412. For example, for the sake of clarity, FIG. 6 illustrates a partial structural diagram corresponding to a first connection via hole 512 in FIG. 1; FIG. 7 is a schematic cross-sectional view of the partial structure of the display substrate illustrated in FIG. 6 along line B2-B2′.

For example, as illustrated in FIG. 1 and FIG. 6, the first sub-transmission portion 412 and the first type transmission portion 312 extend in the same direction, and an orthographic projection of the first sub-transmission portion 412 on the base substrate is basically coincident with an orthographic projection of the first type transmission portion 312 on the base substrate. Therefore, it can be seen from FIG. 1 that both of the signal transmission direction of the first sub-transmission portion 412 and the signal transmission direction of the first type transmission portion 312 are the second direction Y.

For example, as illustrated in FIG. 6 and FIG. 7, the first type transmission portion 312 includes an edge 3121 extending in the first direction X, and an orthographic projection of at least a portion of the edge 3121 on the base substrate falls into an orthographic projection of the first connection via hole 512 on the base substrate 10.

For example, as illustrated in FIG. 6 and FIG. 7, the first type transmission portion 312 and the first sub-transmission portion 412 may each include a portion located in the first connection via hole 512 and a portion overlapping with the edge of the first connection via hole 512 and extending in the second direction Y. Because the portion of the first type transmission portion 312 that is connected with the first sub-transmission portion 412 through the first connection via hole 512 includes an end portion of the first type transmission portion 312, in the second direction Y, the portion of the first type transmission portion 312 that overlaps with the edge of the first connection via hole 512 and extends in the second direction Y may be located on one side of the first connection via hole 512, the edge 3121 of the type transmission portion 312 that extends in the first direction X is located at the above-mentioned end portion of the first type transmission portion 312, and the edge 3121 is located in the first connection via hole 512, which can reduce the size of the first type transmission portion 312 in the second direction Y while not affecting the signal transmission of the first type transmission portion 312.

For example, as illustrated in FIG. 6 and FIG. 7, the first sub-transmission portion 412 extending in the second direction Y includes an edge 4121 extending in the first direction X, and an orthographic projection of at least a portion of the edge 4121 on the base substrate 10 also falls into the orthographic projection of the first connection via hole 512 on the base substrate 10.

For example, as illustrated in FIG. 6 and FIG. 7, the portion of the first sub-transmission portion 412 performing connection through the first connection via hole 512 includes an end portion of the first sub-transmission portion 412, and a portion of the first sub-transmission portion 412 overlapping with the edge of the first connection via hole 512 and extending in the second direction Y is located on one side of the first connection via hole 512, and in the second direction Y, the portion of the first sub-transmission portion 412 located outside the first connection via hole 512 and the portion of the first type transmission portion 312 outside the first connection via hole 512 are located on the same side of the first connection via hole 512, the edge 4121 of the first sub-transmission portion 412 extends in the first direction X is located at the above-mentioned end portion of the first sub-transmission portion 412, and the edge 4121 is located in the first connection via hole 512, so that the size of the first sub-transmission portion 412 in the second direction Y can be reduced while not affecting the signal transmission of the first sub-transmission portion 412.

For example, as illustrated in FIG. 6 and FIG. 7, in the first direction, the size of the portion of first type transmission portion 312 located in the first connection via hole 512 is smaller than the size of the first connection via hole 512, and the size of the portion of first sub-transmission portion 412 located in the first connection via hole 512 is also smaller than the size of the first connection via hole 512. For example, at least a portion of each of the opposite edges of the first type transmission portion 312 extending in the second direction Y is located in the first connection via hole 512, and at least a portion of each of the opposite edges of the first sub-transmission portion 412 extending in the second direction Y is also located in the first connection via hole 512, so that the sizes of the portions of the first type transmission portion 312 and the first sub-transmission portion 412 that overlap with the first connection via hole 512 can be reduced respectively.

For example, in the first direction X, the size of the portion of the first type transmission portion 312 located outside the first connection via hole 512 and located on one side of the first connection via hole 512 in the second direction Y can be equal, or substantially equal to the size of the portion of the first type transmission portion 312 in the first connection via hole 512, which is beneficial to reducing the size of the first type transmission portion 312 in the first direction X as a whole. For example, the size of the portion of the first sub-transmission portion 412 located outside the first connection via hole 512 and located on one side of the first connection via hole 512 in the second direction Y may be equal, or substantially equal to the size of the portion of the first sub-transmission portion 412 located in the first connection via hole 512, which is beneficial to saving the layout space.

For example, as illustrated in FIG. 2 and FIG. 7, the portion of the first connection via hole 512 where the first type transmission portion 312 is not arranged may be filled with the third insulating layer 23, but is not limited thereto.

For example, as illustrated in FIG. 1 and FIG. 2, at least one first sub-transmission portion 41 located in the active semiconductor layer 63 may further include a first sub-transmission portion 413 extending in the first direction X, the plurality of first type transmission portions 31 may include a first type transmission portion 313 extending in the second direction Y, and the first connection via hole 51 located in the first insulating layer 21 includes a first connection via hole 513 through which the first sub-transmission portion 413 and the first type transmission portion 313 are electrically connected. For example, for the sake of clarity, FIG. 8 illustrates a partial structural diagram corresponding to a first connection via hole 513 in FIG. 1; FIG. 9 is a schematic cross-sectional view of the partial structure of the display substrate illustrated in FIG. 8 along line B3-B3′; and FIG. 10 is a schematic cross-sectional view of the partial structure of the display substrate illustrated in FIG. 8 along line A3-A3′.

For example, as illustrated in FIG. 1 and FIG. 8, the first type transmission portion 313 extends in the second direction Y, the first sub-transmission portion 412 extends in the first direction X, and the signal transmission direction of the first type transmission portion 313 is the second direction Y, the signal transmission direction of the first sub-transmission portion 412 is the first direction X.

For example, as illustrated in FIG. 1, FIG. 8 and FIG. 9, the first type transmission portion 313 includes a portion located in the first connection via hole 513, and a portion overlapping with the edge of the first connection via hole 513 and extending in second direction Y. Because the portion of the first type transmission portion 313 that is connected with the first sub-transmission portion 413 through the first connection via hole 513 includes the end portion of the first type transmission portion 313, in the second direction Y, the portion of the first type transmission portion 313 that overlaps with the edge of the first connection via hole 513 and extends in the second direction Y may be located on one side of the first connection via hole 513. The edge of the first type transmission portion 313 extending in the first direction X is located at the above-mentioned end portion of the first type transmission portion 313, and the edge is located in the first connection via hole 513. As illustrated in FIG. 9, in the second direction Y, the size of the portion of the first type transmission portion 313 located in the first connection via hole 513 is smaller than the size of the first connection via hole 513, so that the size of the first type transmission portion 313 in the second direction Y can be reduced while not affecting the signal transmission of the first type transmission portion 313.

For example, as illustrated in FIG. 1, FIG. 8 and FIG. 9, the first sub-transmission portion 413 includes a portion located in the first connection via hole 513, and a portion overlapping with the edge of the first connection via hole 513 and extending in the second direction Y. In the signal transmission direction of the first type transmission portion 313, that is, in the second direction Y, the size of the portion of the first sub-transmission portion 413 located in the first connection via hole 513 is the same as the size of the first connection via hole 513, which is beneficial to having a sufficient contact area with the first type transmission portion 313 and avoiding the portion of the first type transmission portion 313 located in the first connection via hole 513 to be connected with the first sub-transmission portion 413 through “climbing”, so that the portion of the first type transmission portion 313 located in the first connection via hole 513 is smoother and more uniform in structure to facilitate signal transmission.

For example, as illustrated in FIG. 1, FIG. 8 and FIG. 10, an orthographic projection of at least a portion of the two opposite edges of the first type transmission portion 313 extending in the second direction Y on the base substrate 10 falls into the orthographic projection of the first connection via hole 513 on the base substrate 10. An orthographic projection of at least a portion of one edge of the first sub-transmission portion 413 extending in the second direction Y on the base substrate falls into the orthographic projection of the first connection via hole 513 on the base substrate 10.

For example, as illustrated in FIG. 1, FIG. 8 and FIG. 10, in the second direction Y, the size of the portion of the first type transmission portion 313 located in the first connection via hole 513 is smaller than the size of the first connection via hole 513, the size of the portion of the first sub-transmission portion 413 located in the first connection via hole 513 is also smaller than the size of the first connection via hole 513. For example, at least a portion of the two opposite edges of the first type transmission portion 313 extending in the second direction Y is located in the first connection via hole 513, and at least a portion of one edge of the first sub-transmission portion 413 extending in the second direction Y is located in the first connection via hole 513, so that the size of the portion of the first type transmission portion 313 that overlaps with the first connection via hole 513 and the size of the portion of the first sub-transmission portion 413 that overlaps with the first connection via hole 513 can be reduced respectively, so as to reduce the layout area occupied by the first type transmission portion 313 and the first sub-transmission portion 413 and save the layout space.

For example, as illustrated in FIG. 2 and FIG. 9, the portion of the first connection via hole 513 where the first type transmission portion 313 is not arranged may be filled with the third insulating layer 23, but is not limited thereto.

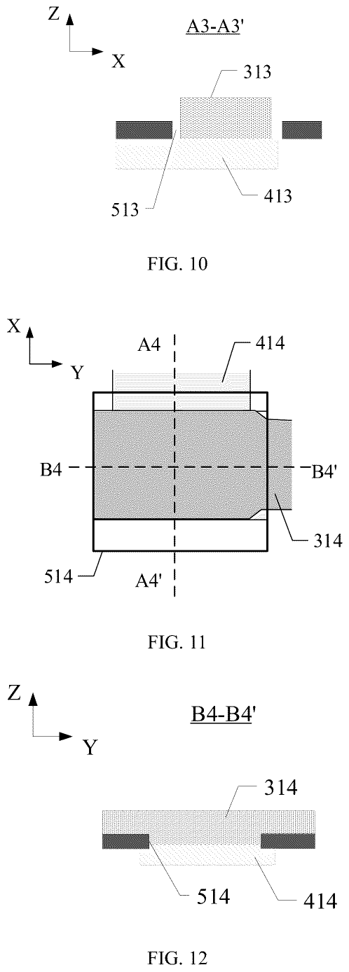

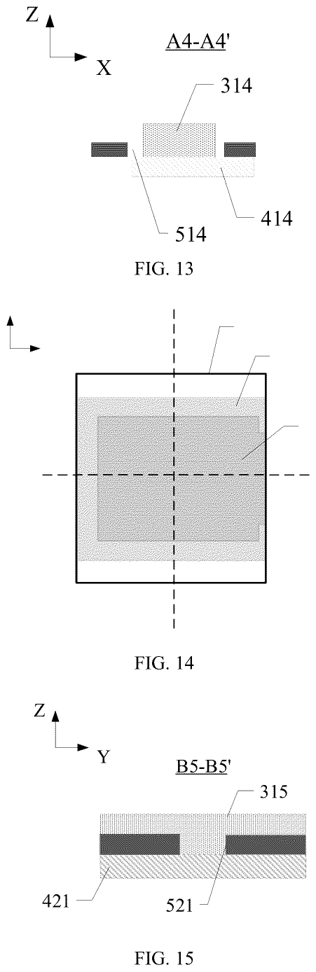

For example, as illustrated in FIG. 1, at least one first sub-transmission portion 41 located in the active semiconductor layer 63 includes a first sub-transmission portion 414 extending in the first direction X, the plurality of first type transmission portions 31 include a first type transmission portion 314 extending in the second direction Y, the first connection via hole 51 located in the first insulating layer 21 includes a first connection via hole 514 through which the first sub-transmission portion 414 and the first type transmission portion 314 are electrically connected. For example, for the sake of clarity, FIG. 11 illustrates a partial structural diagram corresponding to a first connection via hole 514 in FIG. 1; FIG. 12 is a schematic cross-sectional view of the partial structure of the display substrate illustrated in FIG. 11 along line B4-B4′; FIG. 13 is a schematic cross-sectional view of the partial structure of the display substrate illustrated in FIG. 11 along line A4-A4′.

For example, as illustrated in FIG. 1 and FIG. 11, the first type transmission portion 314 extends in the second direction Y, the first sub-transmission portion 414 extends in the first direction X, and the signal transmission direction of the first type transmission portion 314 is the second direction Y, the signal transmission direction of the first sub-transmission portion 414 is the first direction X. For example, in some embodiments of the present disclosure, in the case where a plurality of insulating layers are arranged between the first sub-transmission portion 414 and the first type transmission portion 314, for example, as illustrated in FIG. 2, in the case where the second insulating layer 22 is arranged between the first sub-transmission portion 414 and the first type transmission portion 314 and is located on the side of the first insulating layer 21 away from the base substrate 10, the first connection via hole 514 penetrates the first insulating layer 21 and the second insulating layer 22 in the third direction Z, but is not limited thereto. For example, only the first insulating layer 21 can be arranged between the first sub-transmission portion 414 and the first type transmission portion 314, which is not limited in the embodiments of the present disclosure.

For example, as illustrated in FIG. 1, FIG. 11 and FIG. 12, the first type transmission portion 314 includes a portion located in the first connection via hole 514, and a portion overlapping with the edge of the first connection via hole 514 and extending in the second direction Y. In the second direction Y, the portion of the first type transmission portion 314 overlapping with the edge of the first connection via hole 514 and extending in the second direction Y may be located on both sides of the first connection via hole 514, so that the size of the portion of the first type transmission portion 314 located in the first connection via hole 514 in the second direction Y is equal to the size of the first connection via hole 514 in the second direction Y, so as to facilitate the signal transmission of the first type transmission portion 314.

For example, as illustrated in FIG. 1, FIG. 11 and FIG. 12, the first sub-transmission portion 414 includes a portion located in the first connection via hole 514, and a portion overlapping with the edge of the first connection via hole 514 and extending in the first direction X. In the signal transmission direction of the first type transmission portion 314, that is, in the second direction Y, the size of the portion of the first sub-transmission portion 414 located in the first connection via hole 514 is equal to the size of the first connection via hole 514, which is beneficial to having a sufficient contact area with the first type transmission portion 314 and avoiding the portion of the first type transmission portion 314 located in the first connection via hole 514 to be connected with the first sub-transmission portions 414 through “climbing”, so that the portion of the first type transmission portion 314 located in the first connection via hole 514 is smoother and more uniform in structure to facilitate signal transmission.

For example, as illustrated in FIG. 1, FIG. 11 and FIG. 13, an orthographic projection of at least a portion of one edge of the first sub-transmission portion 414 extending in the second direction Y on the base substrate falls into the orthographic projection of the first connection via hole 514 on the base substrate, and an orthographic projection of a portion of the two opposite edges of the first type transmission portion 314 extending in the second direction Y on the base substrate falls into the first connection via hole 514 on the base substrate.

For example, as illustrated in FIG. 1, FIG. 11 and FIG. 13, in the first direction X, the size of the portion of the first type transmission portion 314 located in the first connection via hole 514 is smaller than the size of the first connection via hole 514, the size of the portion of the first sub-transmission portion 414 located in the first connection via hole 514 is also smaller than the size of the first connection via hole 514. For example, at least a portion of the two opposite edges of the first type transmission portion 314 extending in the second direction Y is located in the first connection via hole 514, and at least a portion of one edge of the first sub-transmission portion 414 extending in the second direction Y is located in the first connection via hole 514, so that the size of the portion of the first type transmission portion 314 and the size of the portion of the first sub-transmission portion 414 that overlap with the first connection via hole 514 can be reduced respectively, so as to reduce the layout area occupied by the first type transmission portion 314 and the first sub-transmission portion 414 and save the layout space.

For example, as illustrated in FIG. 2, the plurality of second transmission portions 40 further include at least one second sub-transmission portion 42 located between the conductive layer 30 and the active semiconductor layer 63, the insulating layer 20 in the display substrate 01 includes a second insulating layer 22 located between the plurality of first transmission portions 30 and the second sub-transmission portion 42, and the plurality of connection via holes 50 includes a second connection via hole 52 located in the second insulating layer 22 (as illustrated in FIG. 1), the plurality of first transmission portions 30 include a second type transmission portion 32, and the second type transmission portion 32 is connected with the second sub-transmission portion 42 through the second connection via hole 52.

For example, as illustrated in FIG. 2, the second sub-transmission portion 42 may be located in a layer where the gate line is located, for example, the second sub-transmission portion 42 may be at least a portion of the gate line, but is not limited thereto. For example, the second sub-transmission portion 42 may be made of molybdenum, but is not limited thereto. For example, at least one second sub-transmission portion 42 may include a plurality of second sub-transmission portions 42, and the plurality of second sub-transmission portions 42 may have different shapes and have different extension directions. For example, the plurality of first sub-transmission portions 42 may be configured to be electrically connected with different signal lines to transmit different electrical signals. For example, the first transmission portion 30 may be a portion of a signal line, and after the first transmission portion 30 is connected with the second sub-transmission portion 42 through the first connection via hole 52, the first transmission portion 30 may perform electrical signal transmission with the first sub-transmission portion 42, but is not limited to this.

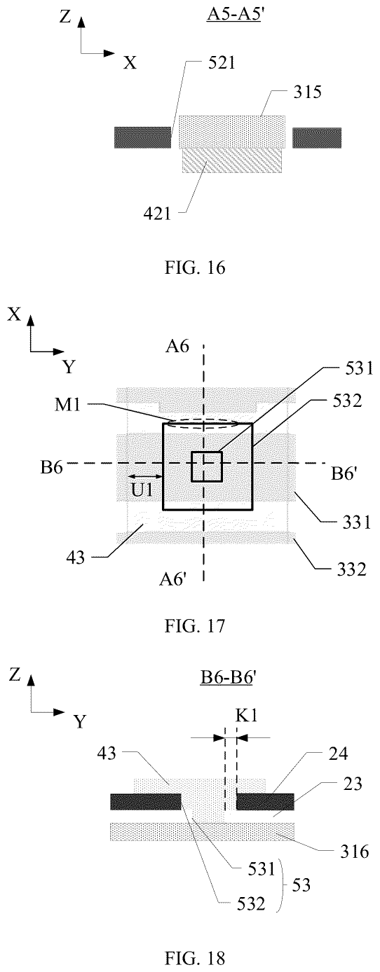

For example, as illustrated in FIG. 1 and FIG. 2, the at least one second sub-transmission portion 42 located between the conductive layer 30 and the active semiconductor layer 63 includes a second sub-transmission portion 421 extending in the second direction Y, and the plurality of second type transmission portions 32 may include a second type transmission portion 315 extending in the second direction Y, and the second connection via hole 52 located in the second insulating layer 22 includes a second connection via hole 521 through which the second sub-transmission portion 421 and the second type transmission portion 315 are electrically connected. For the sake of clarity, FIG. 14 illustrates a partial structural diagram corresponding to a second connection via hole 521 in FIG. 1; FIG. 15 is a schematic cross-sectional view of the partial structure of the display substrate illustrated in FIG. 14 along line B5-B5′; and FIG. 16 is a schematic cross-sectional view of the partial structure of the display substrate illustrated in FIG. 14 along line A5-A5′.

For example, as illustrated in FIG. 1, FIG. 14 and FIG. 15, both of the second type transmission portion 315 and the second sub-transmission portion 421 extend in the second direction Y, and the signal transmission direction of the second type transmission portion 315 and the signal transmission direction of the second sub-transmission portion 421 are the second direction Y.

For example, as illustrated in FIG. 1, FIG. 14 and FIG. 15, the second type transmission portion 315 includes a portion located in the second connection via hole 521, and a portion overlapping with the edge of the second connection via hole 521 and extending in the second direction Y. In the second direction Y, the portion of the second type transmission portion 315 that overlaps with the edge of the second connection via hole 521 and extends in the second direction Y may be located on both sides of the second connection via hole 521, so that the size of the portion of the second type transmission portion 315 located in the second connection via hole 521 in the second direction Y is equal to the size of the second connection via hole 521 in the second direction Y, which facilitates the second type transmission portion 315 to perform signal transmission.

For example, as illustrated in FIG. 1, FIG. 14 and FIG. 15, the second sub-transmission portion 421 includes a portion located in the second connection via hole 521, and a portion overlapping with the edge of the second connection via hole 521 and extending in the second direction Y. In the signal transmission direction of the second sub-transmission portion 421, that is, in the second direction Y, the size of the portion of the second sub-transmission portion 421 located in the second connection via hole 521 is equal to the size of the second connection via hole 521, which is beneficial to having a sufficient contact area with the second type transmission portion 315 and avoiding the portion of the second type transmission portion 315 located in the second connection via hole 521 to be connected with the second sub-transmission portion 421 through “climbing”, so that the portion of the second type transmission portion 315 located in the second connection via hole 521 is smoother and more uniform in structure to facilitate signal transmission.

For example, as illustrated in FIG. 1, FIG. 14 and FIG. 16, an orthographic projection of at least a portion of the two opposite edges of the second type transmission portion 315 extending in the second direction Y on the base substrate falls into the orthographic projection of the second connection via hole 521 on the base substrate. An orthographic projection of at least a portion of the two opposite edges of the second sub-transmission portion 421 extending in the second direction Y on the base substrate falls into the orthographic projection of the second connection via hole 521 on the base substrate.

For example, as illustrated in FIG. 1, FIG. 14 and FIG. 16, in the first direction X, the size of the portion of the second type transmission portion 315 located in the second connection via hole 521 is smaller than the size of the second connection via hole 521, the size of the portion of the second sub-transmission portion 421 located in the second connection via hole 521 is also smaller than the size of the second connection via hole 521. For example, at least a portion of the two opposite edges of the second type transmission portion 315 extending in the second direction Y is located in the second connection via hole 521, and at least a portion of the two opposite edges of the second sub-transmission portion 421 extending in the second direction Y is located in the second connection via hole 521, so that the size of the second type transmission portion 315 in the first direction X and the size of the second sub-transmission portion 421 in the first direction X can be reduced respectively, so as to reduce the layout area occupied by the second type transmission portion 315 and the second sub-transmission portion 421 and save the layout space.

For example, as illustrated in FIG. 1, the maximum size of the connection via hole 50 in the second direction Y is larger than the maximum size of the connection via hole 50 in the first direction X. For example, the maximum size of the first connection via hole 50, such as any one of the first connection via holes 511, the first connection via hole 512, the first connection via hole 513 and the first connection via hole 514, in the second direction Y is greater than its maximum size in the first direction X, but is not limited thereto. For example, the maximum size of the second connection via hole 52, such as the second connection via hole 521, in the second direction Y is larger than its maximum size in the first direction X, but is not limited thereto. For example, the orthographic projection of the connection via hole 50 on the base substrate is rectangular or elliptical, which is not limited in the embodiments of the present disclosure.

With this arrangement, the space occupied by the connection via hole 50 in the first direction X can be reduced, thereby reducing the space occupied by the signal line overlapping with the connection via hole 50 (for example, each first transmission portion 30 extending in the second direction Y) in the first direction X to reduce the risk of crosstalk between adjacent signal lines.

For example, as illustrated in FIG. 1, the size of the connection via hole 50 in the second direction Y may be 2 μm to 2.1 μm, and the size of the connection via hole 50 in the first direction X may be 1.4 μm to 1.5 μm. For example, the size of the connection via hole 50 in the second direction Y may be 2 μm to 2.05 μm or 2.05 μm to 2.10 μm, but is not limited thereto. For example, the size of the connection via hole 50 in the first direction X may be 1.4 μm to 1.45 μm or 1.45 μm to 1.50 μm, but is not limited thereto. This arrangement is beneficial to reducing the space occupied by each connection via hole 50 under a high pixel density layout, thereby improving the display effect.

For example, as illustrated in FIG. 1 and FIG. 2, the at least one second sub-transmission portion 42 located between the conductive layer 30 and the active semiconductor layer 63 further includes a second sub-transmission portion 422 extending in the second direction Y, and the plurality of second type transmission portions 32 may include a second type transmission portion 316 extending in the second direction Y, and the second connection via hole 52 located in the second insulating layer 22 includes a second connection via hole 522 through which the second sub-transmission portion 422 and the second type transmission portion 316 are electrically connected.

For example, the partial structure corresponding to the second connection via hole 522 in FIG. 1 can be seen in FIG. 14 to FIG. 16. For example, an orthographic projection of a portion of the two opposite edges of the second type transmission portion 316 extending in the second direction Y on the base substrate falls into an orthographic projection of the second connection via hole 522 on the base substrate. An orthographic projection of a portion of the two opposite edges of the second sub-transmission portion 422 extending in the second direction Y on the base substrate also falls into the orthographic projection of the second connection via hole 522 on the base substrate, so that the layout area occupied by the second type transmission portion 316 and the second sub-transmission portion 422 can be reduced, and the layout space can be saved.

For example, as illustrated in FIG. 2, the plurality of second transmission portions 40 may further include at least one third sub-transmission portion 43 located on the side of the conductive layer 30 away from the base substrate 10, and the third sub-transmission portion 43 is located on the first electrode 611 and the conductive layer 30. For example, the third sub-transmission portion 43 may adopt a composite material composed of Ti/Al/Ti stacked in sequence, but is not limited thereto. For example, the first electrode 611 may adopt indium tin oxide (ITO) or indium zinc oxide (IZO), but is not limited thereto. For example, as illustrated in FIG. 2, the insulating layer 20 in the display substrate 01 includes a third insulating layer 23 and a fourth insulating layer 24 located between the first type transmission portion 31 and at least one third sub-transmission portion 43, and the insulating layer 23 is located between the fourth insulating layer 24 and the base substrate 10.

For example, as illustrated in FIG. 2, the plurality of connection via holes 50 include a third connection via hole 531 located in the third insulating layer 23 and a fourth connection via hole 532 located in the fourth insulating layer 24, the third connection via hole 531 is communicated with the fourth connection via hole 532, and an inner diameter of the third connection via hole 531 is smaller than an inner diameter of the fourth connection via hole 532, the plurality of first transmission portions 30 in the display substrate include a third type transmission portion 33, and the third type transmission portion 33 is connected with the third sub-transmission portion 43 through the third connection via hole 531 and the fourth connection via hole 532. For example, as illustrated in FIG. 1 and FIG. 2, the third type transmission portion 33 and the first type transmission portion 314 may be two portions of the same first transmission portion 30 that are connected with each other, at least a portion of the third type transmission portion 33 is connected with the third sub-transmission portion 43, and at least a portion of the first type transmission portion 314 is connected with the first sub-transmission portion 414, but is not limited thereto.

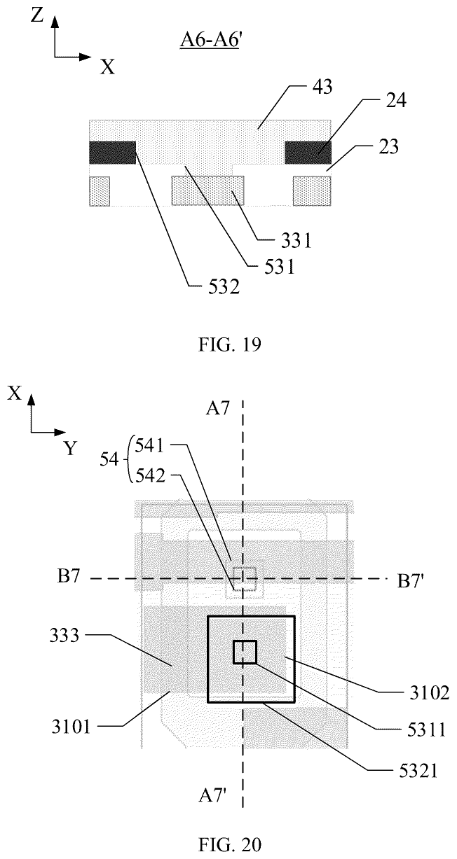

For example, for the sake of clarity, FIG. 17 illustrates a partial structural diagram corresponding to a third connection via hole 531 and a fourth connection via hole 532 in FIG. 1; FIG. 18 is a schematic cross-sectional view of the partial structure of the display substrate illustrated in FIG. 17 along line B6-B6′; FIG. 19 is a schematic cross-sectional view of the partial structure of the display substrate illustrated in FIG. 17 along line A6-A6′.

For example, as illustrated in FIG. 1, FIG. 17 and FIG. 18, the third type transmission portion 33 may include a third type transmission portion 331, and the third connection via hole 531 and the fourth connection via hole 532 are communicated with each other to from a sleeve hole extending in the third direction Z, for example, this design manner can reduce the impact on the third type transmission portion 331 during a formation process of the third sub-transmission portion 43. For example, in some embodiments of the present disclosure, the third sub-transmission portion 43 and the third type transmission portion 331 may adopt the same material. For example, in the process of forming the third sub-transmission portion 43 by etching solution, the etching solution entering into the fourth connection via hole 532 may be blocked from the third connection via hole 531 through the third insulating layer 23, therefore, adopting the form of the sleeve hole can reduce a risk of etching the third type transmission portion 331 by the etching solution.

For example, as illustrated in FIG. 1, FIG. 17 and FIG. 18, both of the maximum size of the third connection via hole 531 in the second direction Y and the maximum size of the third connection via hole 531 in the first direction X are 1 μm to 1.1 μm, for example, they can be 1.05 μm to 1.09 μm or 1.03 μm to 1.07 μm, but are not limited thereto. For example, a distance K1 between the inner wall of the third connection via hole 531 and the inner wall of the fourth connection via hole 532 is 0.7 μm to 0.8 μm, for example, it can be 0.73 μm to 0.78 μm or 0.75 μm to 0.79 μm, but is not limited thereto.

For example, as illustrated in FIG. 1 and FIG. 17, the third type transmission portion 331 extends in the second direction Y, the third sub-transmission portion 43 extends in the first direction X, and the signal transmission direction of the third type transmission portion 331 is the second direction Y, the signal transmission direction of the third sub-transmission portion 43 is the first direction X.

For example, as illustrated in FIG. 1, FIG. 17 and FIG. 18, the third type transmission portion 331 includes a portion located in the third connection via hole 531, and a portion overlapping with the edge of the third connection via hole 531 and extending in the second direction Y. In the second direction Y, the portion of the third type transmission portion 331 that overlaps with the edge of the third connection via hole 531 and extends in the second direction Y may be located on both sides of the third connection via hole 531, so that the size of the portion of the third type transmission portion 331 located in the third connection via hole 531 in the second direction Y is equal to the size of the third connection via hole 531 in the second direction Y, which facilitates the third type transmission portion 331 to perform signal transmission.

For example, as illustrated in FIG. 1, FIG. 17 and FIG. 18, the third sub-transmission portion 43 includes a portion located in the third connection via hole 531, a portion located in the fourth connection via hole 532, and a portion overlapping with the edge of the fourth connection via hole 532. For example, the third sub-transmission portion 43 extends in the first direction X, so that the third sub-transmission portion 43 includes a portion that overlaps with the edge of the fourth connection via hole 532 and extends in the first direction X. For example, the third sub-transmission portion 43 further includes a portion that overlaps with the edge of the fourth connection via hole 532 and extends in the second direction Y, so that an orthographic projection of the fourth connection via hole 532 on the base substrate 10 falls into an orthographic projection of the third sub-transmission portion 43 on the base substrate 10 to reduce a risk that in the case where the third sub-transmission portion 43 is broken at the edge of the fourth connection via hole 532, the third sub-transmission portion 43 cannot be electrically connected with the third type transmission portion 331.

For example, a region that may cause the third sub-transmission portion 43 to be broken may be an edge portion M of the fourth connection via hole 532 illustrated in FIG. 17, but is not limited thereto. For example, in the second direction Y, a distance U1 between the edge of the third sub-transmission portion 43 extending in the first direction X and the fourth connection via hole 532 can be 2.7 μm to 2.8 μm, such as at least one of 2.73 μm to 2.75 μm, 2.74 μm to 2.76 μm, and 2.75 μm to 2.78 μm, but is not limited thereto.

For example, as illustrated in FIG. 1, FIG. 17 and FIG. 18, an orthographic projection of another third type transmission portion 332 adjacent to and arranged at intervals with the third type transmission portion 331 on the base substrate falls into an orthographic projection of the fourth insulating layer 24 on the base substrate. For example, because the third type transmission portion 331 and the third type transmission portion 332 that are adjacent to and arranged at intervals with each other in the first direction X are configured to transmit different signals, therefore, by arranging the fourth insulating layer 24 to cover the side of the third type transmission portion 332 away from the base substrate, a risk of a short circuit between the third sub-transmission portion 43 and the third type transmission unit 332 can be reduced while the third sub-transmission portion 43 is electrically connected with the third type transmission portion 331.

For example, as illustrated in FIG. 1, FIG. 17 and FIG. 19, an orthographic projection of a portion of the two opposite edges of the third type transmission portion 331 extending in the second direction Y on the base substrate falls into an orthographic projection of the fourth connection hole 532 on the base substrate. For example, in the first direction X, the size of the portion of the third type transmission portion 331 located in the fourth connection via hole 532 is smaller than the size of the fourth connection via hole 532, so that a size of an overlapping portion between the third type transmission portion 331 and the fourth connection via hole 532 can be reduced, and so as to reduce the layout area occupied by the third type transmission portion 331, and save the layout space. For example, in the first direction X, the size of the portion of the third type transmission portion 331 located in the fourth connection via hole 532 is larger than the size of the third connection via hole 531, which facilitates a good electrical connection with the third sub-transmission portion 43.

For example, as illustrated in FIG. 1, FIG. 17 and FIG. 19, the third sub-transmission portion 43 extends in the first direction X, and the third sub-transmission portion 43 completely covers the fourth connection via hole 532. For example, in the first direction X, the size of the portion of the third sub-transmission portion 43 located in the fourth connection via hole 532 is the same as the size of the fourth connection via hole 532, and the third sub-transmission portion 43 further includes a portion that overlaps with the edge of the fourth connection via hole 532 and extending in the first direction X, thereby enabling a good electrical connection with the third sub-transmission unit 43.

For example, as illustrated in FIG. 2, the display substrate 01 further includes an anode insulating layer 25 located between the first electrode 611 and the third sub-transmission portion 43, the anode insulating layer 25 includes an anode connection via hole 54, through which the first electrode 611 is connected with the third sub-transmission portion 43.

For example, as illustrated in FIG. 1, the display substrate 01 further includes another fourth connection via hole 5321 arranged immediately adjacent to the anode connection via hole 54, and a third connection via hole 5311 located on a side of the fourth connection via hole 5321 close to the base substrate, an orthographic projection of the anode connection via hole 54 does not overlap with an orthographic projection of the fourth connection via hole 5321 on the base substrate. For example, the anode connection via hole 54 and the fourth connection via hole 5321 are arranged sequentially in the first direction X, but are not limited thereto.

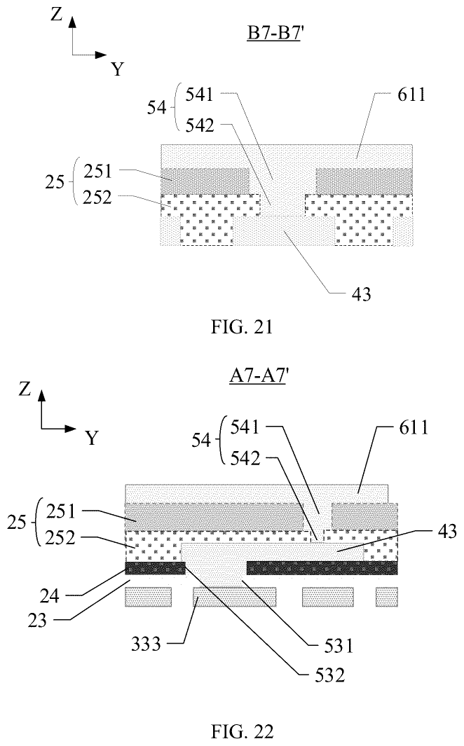

For the sake of clarity, FIG. 20 illustrates a partial structural diagram corresponding to the anode connection via hole 54 and the fourth connection via hole 5321 in FIG. 1; FIG. 21 is a schematic cross-sectional view of the partial structure of the display substrate illustrated in FIG. 20 along line B7-B7′; and FIG. 22 is a schematic cross-sectional view of the partial structure of the display substrate illustrated in FIG. 20 along line A7-A7′.

For example, as illustrated in FIG. 1, FIG. 20 and FIG. 21, the anode insulating layer 25 may include a first anode insulating sub-layer 251 and a second anode insulating sub-layer 252, and the second anode insulating sub-layer 252 is further away from the first electrode 611 than the first anode insulating sub-layer 251. The anode connection via hole 54 includes a first anode connection via hole 541 located in the first anode insulating layer 251 and a second anode connection via hole 542 located in the second anode insulating sub-layer 252, the first anode connection via hole 541 is communicated with the second anode connection via hole 542, the first electrode 611 is connected with the third sub-transmission portion 43 through the first anode connection via hole 541 and the second anode connection via hole 542. For example, the first anode connection via hole 541 and the second anode connection via hole 542 are communicated with each other to from a sleeve hole extending in the third direction Z, for example, this design manner can reduce the impact on the third sub-transmission portion 43 during a formation process of the anode insulating layer 25. For example, an orthographic projection of the anode connection via hole 54 on the base substrate falls into an orthographic projection of the first electrode 611 on the base substrate, and falls into an orthographic projection of the third sub-transmission portion 43 on the base substrate, so that the first electrode 611 and the third sub-transmission portion 43 can be effectively electrically connected through the anode connection via hole 54.

For example, as illustrated in FIG. 20 and FIG. 22, the first electrode 611 is connected with the third sub-transmission portion 43 through the first anode connection via hole 541 and the second anode connection via hole 542, and the third type transmission portion 33 includes a third type transmission portion 333, and the third type transmission portion 333 is connected with the third sub-transmission portion 43 through the third connection via hole 531 and the fourth connection via hole 532, and the anode connection via hole 54 and the fourth connection via hole 5321 are staggered from each other in the first direction X, which is beneficial to the manufacturing process and enables effectively electrical connection between the first electrode 611 and the first transmission portion 316.

For example, as illustrated in FIG. 20, both of an orthographic projection of at least a portion of the edge 3101 of the third type transmission portion 333 extending in the second direction Y and away from the anode connection via hole 54 and an orthographic projection of at least a portion of the edge 3102 of the third type transmission portion 333 extending in the first direction X on the base substrate fall into an orthographic projection of the fourth connection via hole 5321 on the base substrate.

For example, as illustrated in FIG. 20 and FIG. 22, the portion of the third type transmission portion 333 that is connected with the fourth connection via hole 532 includes the end portion of the third type transmission portion 333, by arranging at least a portion of the edge 3101 of the third type transmission portion 333 extending in the second direction Y and away from the anode connection via hole 540 to be located in the fourth connection via hole 532, the size of the third type transmission portion 333 in the first direction X can be reduced, which is beneficial to saving layout area occupied by the third type transmission portion 333. For example, by arranging a portion of the edge 3102 of the third type transmission portion 333 extending in the first direction X to be located in the fourth connection via hole 532, the size of the third type transmission portion 333 in the second direction Y can be reduced, which is beneficial to saving the layout space.

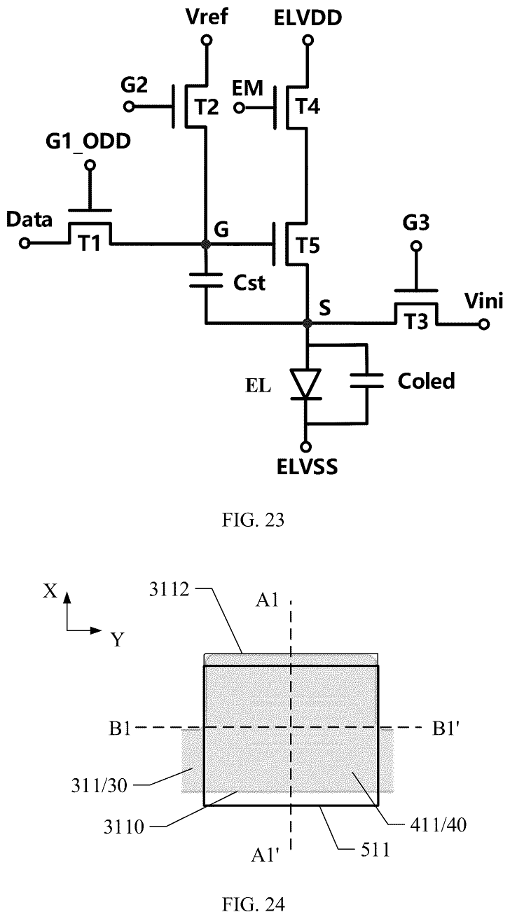

FIG. 23 is a schematic diagram of a pixel circuit corresponding to a display substrate provided by at least one embodiment of the present disclosure. As illustrated in FIG. 23, the pixel circuit includes a data writing transistor T1, a first reset transistor T2, a second reset transistor T3, a light-emitting control transistor T4, a driving transistor T5 and a storage capacitor Cst. For example, the pixel circuit illustrated in FIG. 1 can be a 5T1C circuit structure (that is, five transistors and one capacitor).

For example, as illustrated in FIG. 1 and FIG. 23, the gate electrode of the driving transistor T5 is electrically connected with the second electrode of the data writing transistor T1 and the second electrode of the first reset transistor T2, respectively, and the first electrode of the driving transistor T5 is electrically connected with the second electrode of the light-emitting control the transistor T4, and the second electrode of the driving transistor T5 is electrically connected with the first terminal of the light-emitting element EL and the second electrode of the second reset transistor T3, respectively. For example, the first electrode of the data writing transistor T1 is configured to be electrically connected with the data line Data to receive the data signal, and the gate electrode of the data writing transistor T1 is electrically connected with a first gate line G1_ODD and is configured to write the data signal to the gate electrode of driving transistor T5 in response to the first control signal. For example, the first electrode of the first reset transistor T2 is electrically connected with a reset signal line Vref, the gate electrode of the first reset transistor T2 is electrically connected with the second gate line G2 and is configured to transmit the reference voltage to the gate electrode of the driving transistor T5 in response to the second control signal. For example, the first electrode of the second reset transistor T3 is electrically connected with the reset signal line Vini, the gate electrode of the second reset transistor T3 is electrically connected with a third gate line G3 and is configured to transmit an initialization voltage to the second electrode of the driving transistor T5 and the first terminal of the light-emitting element EL in response to the third control signal. For example, the first electrode of the light-emitting control transistor T4 is electrically connected with the first power supply ELVDD, the gate electrode of the light-emitting control transistor T4 is electrically connected with the light-emitting control signal line EM and is configured to transmit the first power supply voltage to the first electrode of the driving transistor T5 in response to the light-emitting control signal. For example, the first electrode plate of the storage capacitor Cst is electrically connected with the gate electrode of the driving transistor T5, the second electrode plate of the storage capacitor Cst is electrically connected with the second electrode of the driving transistor T5, and the storage capacitor Cst is configured to store the data signal. For example, the second terminal of the light-emitting element EL is electrically connected with the second power supply ELVSS. For example, a capacitor Coled is provided in parallel at both ends of the light-emitting element EL.

For example, as illustrated in FIG. 23, the driving method of the pixel circuit includes: a reset phase, a compensation phase, a data writing phase and a light-emitting phase.

For example, during the reset phase, both of the signal of the second gate line G2 and the signal of the third gate line G3 are high level signals, both of the signal of the first gate line G1_ODD and the signal of the light-emitting control signal line EM are low level signals, the second control signal and the third control signal are input, the first reset transistor T2 and the second reset transistor T3 are turned on, the data writing transistor T1 and the light-emitting control transistor T4 are turned off, the reference voltage is transmitted to the gate electrode of the driving transistor T5 through the first reset transistor T2 to rest the gate electrode of the driving transistor T5, and the initialization voltage is transmitted to the second electrode of the driving transistor T5 and the first terminal of the light-emitting element EL through the second reset transistor T3, so as to reset the second electrode of the driving transistor T5 and the first terminal of the light-emitting element EL.

For example, in the compensation stage, both of the signal of the second gate line G2 and the signal of the light-emitting control signal line EM are high level signals, both of the signal of the first gate line G1_ODD and the signal of the third gate line G3 are low level signals, the second control signal and the light-emitting control signal are input, the first reset transistor T2 is kept being turning on, the data writing transistor T1 and the second reset transistor T3 are turned off, and the light-emitting control transistor T4 and the driving transistor T5 are turned on, and the second electrode of the driving transistor T5 is charged through the first power supply VDD to compensate the driving transistor T5.

For example, during the data writing phase, the signal of the first gate line G1_ODD is a high level signal, the signal of the second gate line G2, the signal of the third gate line G3 and the signal of the light-emitting control signal line EM are all low level signals, the data writing transistor T1 is turned on, other transistors are turned off, the voltage of the gate electrode of the driving transistor T5 jumps from the reference voltage to the data voltage, the voltages of the two electrode plates of the storage capacitor Cst jump accordingly, and the storage capacitor Cst is charged.

For example, during the light-emitting phase, the voltage of the light-emitting control signal line EM is a high level signal, the voltage of the first gate line G1_ODD, the voltage of the second gate line G2, and the voltage of the third gate line G3 are all low level signals, and the light-emitting control transistor T4 and the driving transistor T5 are turned on to generate driving current, thereby driving the light-emitting element EL to emit light. The data writing transistor T1, the first reset transistor T2 and the second reset transistor T3 are turned off.

Currently, the compensation methods for transistors are divided into internal compensation and external compensation, because the internal compensation is adaptive and with a simple external driving integrated circuit (IC), the pixels with the pixel circuit illustrated in FIG. 23 are widely used in the small-size display device.

FIG. 24 illustrates a partial structural diagram corresponding to the first connection via hole 511 in FIG. 1 in another embodiment of the present disclosure.

For example, in some embodiments of the present disclosure, referring to FIG. 1, the display substrate 01 may further include a first adjacent transmission portion 3111 and a second adjacent transmission portion that are adjacent to and arranged at intervals with the first transmission portion 30, such as the first type transmission portion 311 in the first direction X, and the first adjacent transmission portion 3111 is closer to the first type transmission portion 311 than the second adjacent transmission portion.

For example, referring to FIG. 1 and FIG. 24, the first type transmission portion 311 may include a first edge 3110 close to the first adjacent transmission portion 3111 and a second edge 3112 close to the second adjacent transmission portion, both of the first edge 3110 and the second edge 3112 extend in the second direction Y, and an area of an orthographic projection of a portion of the first edge 3110 on the base substrate that falls into the connection via hole is larger than an area of an orthographic projection of the second edge 3112 on the base substrate that falls into the connection via hole. For example, the connection via hole may be the first connection via hole 511 corresponding to the first type transmission portion 311, but is not limited thereto.

For example, referring to FIG. 1 and FIG. 24, in the first direction X, in the case where the space between the first type transmission portion 311 and the first adjacent transmission portion 3111 is relatively small, and the space between the first type transmission portion 311 and the second adjacent transmission portion is relatively loose, the portion of the second edge 3112 of the first type transmission portion 311 falls into the first connection via hole 511 can be less, so as to increase a contact area of the first type transmission portion 311 and the first sub-transmission portion 411 in the first connection via hole 511, and further improve the signal transmission efficiency. For example, as illustrated in FIG. 24, only at least a portion of the first edge 3110 falls into the first connection via hole 511, and the second edge 3112 is located outside the first connection via hole 511. For example, in some embodiments of the present disclosure, a portion of the second edge 3112 can fall into the first connection via hole 511, and an orthographic projection of this portion on the base substrate is smaller than an orthographic projection of a portion of the first edge 3110 falling into the first connection via hole 511 on the base substrate, but is not limited thereto. For example, an area of the orthographic projection of the portion of the second edge 3112 falling into the first connection via hole 511 on the base substrate can be at least one of 20% to 60%, 30% to 50%, 35% to 45%, 40% to 55%, and 25% to 30% of an area of the orthographic projection of the portion of the first edge 3110 falling into the first connection via hole 511 on the base substrate, which can be set according to the layout space.

With this arrangement, while the space between the first type transmission portion 311 and the first adjacent transmission portion 3111 can be saved, the signal transmission efficiency is improved.

Similarly, the above design manner is not limited to the first type transmission portion 311, other first transmission portions in the display substrate 01 can further be designed accordingly according to the layout space, and the embodiments of the present disclosure do not limit this.

For example, in some embodiments of the present disclosure, referring to FIG. 1, depending on the signal transmitted in the first transmission portion, for example, the area of the orthographic projection of the portion of the third type transmission portion 331 located in the fourth connection via hole 532 on the base substrate is larger than an area such as the area of the orthographic projection of the portion of the first type transmission portion 313 located in the first connection via hole 513 on the base substrate. For example, the first type transmission portion 313 can transmit the initialization voltage signal as illustrated in FIG. 23 in the above embodiment, and the third type transmission portion 331 can transmit the first power supply ELVDD in the above embodiment, but is not limited thereto. With this arrangement, the third type transmission portion 331 can have a larger overlapping area with the third sub-transmission portion 43 (as illustrated in FIG. 2) in the fourth connection via hole 532 to facilitate signal transmission of the first power supply ELVDD and improve the signal transmission efficiency.

For example, in some embodiments of the present disclosure, the data line Data in the display substrate 01 is as illustrated in FIG. 1, for example, in the case where the data line Data is connected with another signal line through a via hole, an orthographic projection of the data line Data on the base substrate completely covers an orthographic projection of the via hole on the base substrate, so that the data signal can be effectively transmitted, but is not limited thereto.

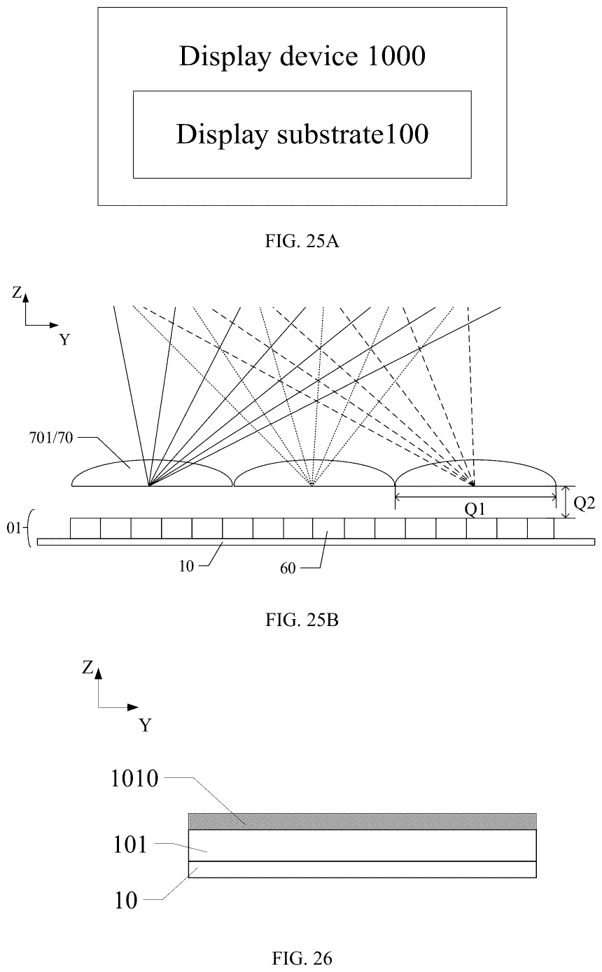

At least one embodiment of the present disclosure further provides a display device, including any one of the above display substrates. FIG. 25A is a schematic diagram of a display device provided by an embodiment of the present disclosure. As illustrated in FIG. 25A, the display device 1000 includes a display substrate 100. The display substrate 100 is any one of the above display substrates. Therefore, the technical effects of the above-mentioned display substrate can further be reflected in the display device, which will not be described again here.

FIG. 25B is a schematic diagram of another display device provided by an embodiment of the present disclosure.

For example, as illustrated in FIG. 25B, according to at least one embodiment of the present disclosure, the display device 1000 further includes a plurality of sub-pixels 60 and a light-splitting structure 70, and the plurality of sub-pixels 60 are located on the base substrate 10. The light-splitting structure 70 is arranged on a light exiting side of the display substrate 01, and the light-splitting structure 70 is configured to direct the light emitted by the plurality of sub-pixels 60 to different viewpoint regions. The light-splitting structure 70 includes a plurality of light-splitting portions 701 extending in the first direction X and arranged in the second direction Y, and the light-splitting portion 701 includes a lens.

For example, the display device provided by the embodiment of the present disclosure is a 3D display device. As illustrated in FIG. 25B, one light-splitting portion 701 may be provided with several sub-pixels 60, for example, may be corresponding to several sub-pixels 60 of different colors. For example, each sub-pixel 60 may include a plurality of display units, and the plurality of display units of each sub-pixel may respectively display images corresponding to the left eye and the right eye of the human. Therefore, after viewpoint image information displayed by each sub-pixel is processed through its corresponding light-splitting portion, naked-eye 3D images can be formed.

For example, the light-splitting portion 701 may include a cylindrical lens, but is not limited thereto. For example, the size of the light-splitting portion 701 in the second direction Y and the distance between the light-splitting portion 701 and the display substrate 01 in the third direction Y can be set according to design requirements, and the embodiments of the present disclosure do not limit this.

The display substrate mentioned in the embodiments of the present disclosure may also be called a display panel. For example, the display substrate may be a flexible display substrate, but is not limited thereto. For example, the display device 1000 can be a display device such as an organic light-emitting diode display device, as well as any product or component including the display device and with a display function such as a television, a digital camera, a mobile phone, a watch, a tablet computer, a notebook computer, a navigator, etc., the embodiments of the present disclosure include, but are not limited thereto.

At least one embodiment of the present disclosure further provides a manufacturing method of a display substrate, including: forming an insulating layer, a conductive layer and a plurality of second transmission portions on a base substrate, the conductive layer is located on a side of the insulating layer, the plurality of second transmission portions are located on a side of the insulating layer away from the conductive layer. For example, the second transmission portion may be located on a side of the conductive layer away from the base substrate, or may be located on a side of the conductive layer close to the base substrate, the embodiments of the present disclosure do not limit this. In the following, the case where the second transmission portion is located on the side of the conductive layer away from the base substrate is taken as an example to be illustrated.

FIG. 26 to FIG. 31 are schematic flow diagrams of a manufacturing method of the display substrate provided by at least one embodiment of the present disclosure.

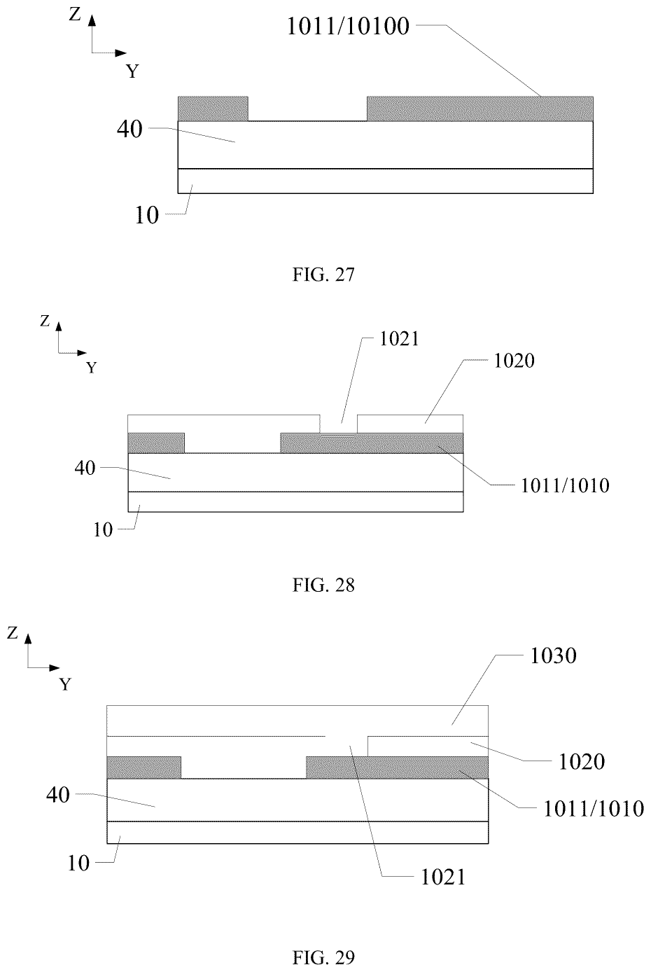

For example, as illustrated in FIG. 26 to FIG. 27, forming the conductive layer includes: depositing a first transmission layer 1010 on the base substrate 10 and patterning the first transmission layer 1010 to form a first pattern 10100, the first pattern 10100 includes a plurality of first transmission portions 1011. For example, the first transmission portion 1011 may correspond to the first transmission portion 30 in FIG. 2 of the above embodiment, but is not limited thereto.

For example, as illustrated in FIG. 28, forming the insulating layer includes: depositing an insulating layer 1020 on a side of the first transmission portion 1011 and patterning the insulating layer 1020 so that the insulating layer 1020 includes at least one connection via hole 1021. For example, the insulating layer 1020 may correspond to the third insulating layer 23 and the fourth insulating layer 24 in FIG. 2 of the above embodiment, but is not limited thereto.

For example, as illustrated in FIG. 29, forming a plurality of second transmission portions includes: forming a second transmission layer 1030, for example, the second transmission layer 1030 is located on a side of the insulating layer 1020 away from the first transmission portion 1011, but is not limited thereto.

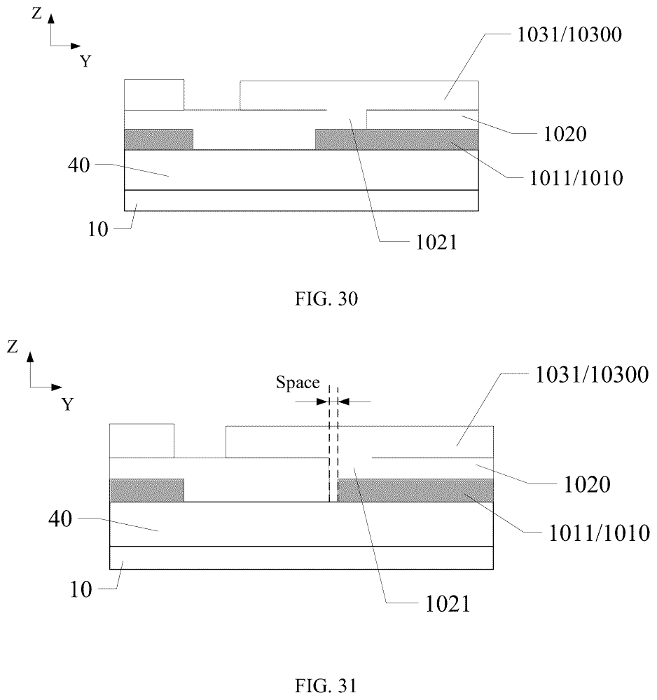

For example, as illustrated in FIG. 30, the second transmission layer 1030 is patterned to form a second pattern 10300, and the second pattern 10300 includes a plurality of second transmission portions 1031. For example, the insulating layer 1020 may correspond to the second transmission portion 40 in the above embodiment, for example, may correspond to the third sub-transmission portion 43 in FIG. 2 of the above embodiment, but is not limited thereto.

For example, as illustrated in FIG. 31, the first transmission portion 1011 is electrically connected with at least one second transmission portion 1031 through at least one connection via hole 1021, meanwhile, because the second transmission portion 1031 has a retraction characteristic, in the final state, an orthographic projection of a portion of the edge of at least one first transmission portion 1011 extending in the second direction Y (please refer to FIG. 1) on the base substrate 10 falls into an orthographic projection of the connection via hole 1021 on the base substrate 10, the second direction Y intersects with the first direction X.

For example, as illustrated in FIG. 30, in order to enable at least a portion of the edge of the first transmission portion 1011 extending in the second direction Y to retract into the connection via hole 1021, during the design process, it is necessary to enable an orthographic projection of a portion of the edge of at least one of the first transmission portion 1011 extending in the second direction Y on the base substrate 10 to fall into an orthographic projection of the connection via hole 1021 on the base substrate 10, which includes: setting a distance between a portion of an edge of the at least one first transmission portion extending in the second direction Y and the first connection via hole 1021 as Space, and Space satisfies the following formula:

$$Space \leq \sqrt{OL {1}^{2} + OL {2}^{2} + Tor {1}^{2} + Tor {2}^{2}} + Bias 1 + Bias 2 ,$$

in the formula, OL1 refers to a minimum spacing between a line in the first transmission layer 1010 and a corresponding design position, OL2 refers to a minimum spacing between a line in the second transmission layer 1030 and a corresponding design position, Tor1 refers to a uniformity of the first pattern 10100, Tor2 refers to a uniformity of the second pattern 10300, Bias1 refers to a size accuracy of the first pattern 10100, and Bias2 refers to a size accuracy of the second pattern 10300.

For example, in some embodiments of the present disclosure, as illustrated in FIG. 31, Space can be 1 μm to 1.8 μm, for example, it can be at least one of 1 μm to 1.5 μm, 1.2 μm to 1.7 μm, 1.3 μm to 1.6 μm, 1.4 μm to 1.8 μm, 1.5 μm to 1.7 μm, 1 μm to 1.2 μm, 1.1 μm to 1.2 μm, and can be specifically set according to design requirements, process environment, performance of the exposure machine, etc., and the embodiments of the present disclosure do not limit this.

The display substrate provided by the embodiment of the present disclosure can reduce a coverage area of the first transmission portion outside the edge of the connection via hole and reduce the space occupied by the first transmission portion in the first direction by locating at least a portion of the edge of the first transmission portion extending in the second direction in the connection via hole, which facilitates the layout arrangement and improves the display effect.

The following statements need to be clarified.
(1) In the drawings of the embodiment of the present disclosure, only the structures related to the embodiment of the present disclosure are involved, and other structures can refer to the common designs.
(2) In the case of no conflict, the features in the same embodiment and different embodiments of the present disclosure can be combined with each other.

The above are only exemplary embodiments of the present disclosure, and is not used to limit the protection scope of the present disclosure, which is determined by the appended claims.

1. A display substrate, comprising:
a base substrate;
an insulating layer, located on the base substrate;
a conductive layer, located on a side of the insulating layer, the conductive layer comprising a plurality of first transmission portions arranged in a first direction;
a plurality of second transmission portions, located on a side of the insulating layer away from the conductive layer,
wherein at least one first transmission portion extends in a second direction, a plurality of connection via holes are provided in the insulating layer, and the at least one first transmission portion is electrically connected with at least one second transmission portion through at least one connection via hole;
an orthographic projection of at least a portion of at least one edge of the at least one first transmission portion extending in the second direction on the base substrate falls into an orthographic projection of the connection via hole on the base substrate, the second direction intersects with the first direction.

2. The display substrate according to claim 1, wherein a material of the first transmission portion is different from a material of the second transmission portion.

3. The display substrate according to claim 1, wherein an area of an orthographic projection of an overlapping portion of the first transmission portion and the second transmission portion in the connection via hole on the base substrate is 0.3 to 0.8 of an area of the orthographic projection of the connection via hole on the base substrate.

4. The display substrate according to claim 1, further comprising a plurality of sub-pixels located on the base substrate, wherein each of at least part of the plurality of sub-pixels comprises a light-emitting element and a pixel circuit, and the light-emitting element comprises a light-emitting functional layer and a first electrode and a second electrode located on both sides of the light-emitting functional layer in a direction perpendicular to the base substrate, the first electrode is located between the light-emitting functional layer and the base substrate, the pixel circuit comprises a plurality of transistors, and the first electrode of the light-emitting element is electrically connected with the plurality of transistors.

5. The display substrate according to claim 4, wherein the pixel circuit comprises an active semiconductor layer, the active semiconductor layer comprises a channel region and a source and drain regions of each of the plurality of transistors, and the active semiconductor layer is located between the conductive layer and the base substrate,
the plurality of second transmission portions comprise at least one first sub-transmission portion located in the active semiconductor layer, and the insulating layer comprises a first insulating layer located between the conductive layer and the at least one first sub-transmission portion, the plurality of connection via holes comprise a first connection via hole located in the first insulating layer, the plurality of first transmission portions comprise a first type transmission portion, the first type transmission portion is connected with the first sub-transmission portion through the first connection via hole.

6. The display substrate according to claim 5, wherein the at least one first sub-transmission portion comprises a first sub-transmission portion extending in the second direction, an orthographic projection of at least a portion of two opposite edges of the first sub-transmission portion extending in the second direction on the base substrate falls into an orthographic projection of the first connection via hole on the base substrate, and an orthographic projection of at least a portion of two opposite edges of the first type transmission portion extending in the second direction on the base substrate falls into the orthographic projection of the first connection via hole on the base substrate.

7. The display substrate according to claim 5, wherein the first type transmission portion or the first sub-transmission portion extending in the second direction comprises an edge extending in the first direction, an orthographic projection of at least a portion of the edge extending in the first direction on the base substrate falls into an orthographic projection of the first connection via hole on the base substrate.

8. (canceled)

9. The display substrate according to claim 5, wherein the at least one first sub-transmission portion comprises a first sub-transmission portion extending in the first direction, an orthographic projection of at least a portion of an edge of the first sub-transmission portion extending in the first direction on the base substrate falls into an orthographic projection of the first connection via hole on the base substrate, and an orthographic projection of at least a portion of two opposite edges of the first type transmission portion extending in the second direction on the base substrate falls into the orthographic projection of the first connection via hole on the base substrate.

10. The display substrate according to claim 4, wherein the pixel circuit comprises an active semiconductor layer, the active semiconductor layer comprises a channel region and a source and drain regions of each of the plurality of transistors, and the active semiconductor layer is located between the conductive layer and the base substrate,
the plurality of second transmission portions comprise at least one second sub-transmission portion located between the conductive layer and the active semiconductor layer, and the insulating layer comprises a second insulating layer located between the plurality of first transmission portions and the at least one second sub-transmission portion, the plurality of connection via holes comprises a second connection via hole located in the second insulating layer, the plurality of first transmission portions comprises a second type transmission portion, and the second type transmission portion is connected with the second sub-transmission portion through the second connection via hole,
wherein an orthographic projection of at least a portion of two opposite edges of the second type transmission portion extending in the second direction on the base substrate falls into an orthographic projection of the second connection via hole on the base substrate, an orthographic projection of at least a portion of two opposite edges of the second sub-transmission portion extending in the second direction on the base substrate falls into the orthographic projection of the second connection via hole on the base substrate.

11. (canceled)

12. The display substrate according to claim 5, wherein a maximum size of the connection via hole in the second direction is larger than a maximum size of the connection via hole in the first direction.

13. The display substrate according to claim 6, further comprising a first adjacent transmission portion and a second adjacent transmission portion that are adjacent to and arranged at intervals with the first transmission portion in the first direction, the first adjacent transmission portion being closer to the first transmission portion than the second adjacent transmission portion,
wherein the first transmission portion comprises a first edge close to the first adjacent transmission portion and a second edge close to the second adjacent transmission portion, and both the first edge and the second edge extend in the second direction, and an area of an orthographic projection of a portion of the first edge that falls into the connection via hole on the base substrate is larger than an orthographic projection of a portion of the second edge that falls into the connection via hole on the base substrate.

14. The display substrate according to claim 5, wherein
the plurality of second transmission portions comprise at least one third sub-transmission portion located on a side of the conductive layer away from the base substrate, and the third sub-transmission portion is located between the first electrode and the conductive layer,
the insulating layer comprises a third insulating layer and a fourth insulating layer that are located between the plurality of first transmission portions and the at least one third sub-transmission portion, the third insulating layer is located between the fourth insulating layer and the base substrate, the plurality of connection via holes comprise a third connection via hole located in the third insulating layer and a fourth connection via hole located in the fourth insulating layer, the third connection via hole is communicated with the fourth connection via hole, and an inner diameter of the third connection via hole is smaller than an inner diameter of the fourth connection via hole, the plurality of first transmission portions comprise a third type transmission portion, the third type transmission portion is connected with the third sub-transmission portion through the third connection via hole and the fourth connection via hole.

15. The display substrate according to claim 14, wherein an orthographic projection of at least a portion of two opposite edges of the third type transmission portion extending in the second direction on the base substrate falls into an orthographic projection of the fourth connection via hole on the base substrate,
wherein the third sub-transmission portion extends in the first direction, and the orthographic projection of the fourth connection via hole on the base substrate falls into an orthographic projection of the third sub-transmission portion on the base substrate.

16. (canceled)

17. The display substrate according to claim 14, wherein an area of an orthographic projection of a portion of the third type transmission portion located in the fourth connection via hole on the base substrate is larger than an area of an orthographic projection of a portion of the first type transmission portion located in the first connection via hole on the base substrate.

18. The display substrate according to claim 14, wherein
an orthographic projection of another third type transmission portion adjacent to and arranged at intervals with the third type transmission portion on the base substrate falls into the orthographic projection of the fourth insulating layer on the base substrate.

19. The display substrate according to claim 14, further comprising:
an anode insulating layer, located between the first electrode and the third sub-transmission portion, the anode insulating layer comprises an anode connection via hole, the first electrode is connected with the third sub-transmission portion through the anode connection via hole,
wherein an orthographic projection of the anode connection via hole on the base substrate does not overlap with an orthographic projection of the fourth connection via hole on the base substrate,
orthographic projections of at least a portion of the edge of the third type transmission portion extending in the second direction and away from the anode connection via hole and at least a portion of the edge of the third type transmission portion extending in the first direction on the base substrate fall into an orthographic projection of the third connection via hole on the base substrate.

20. A display device, comprising the display substrate according to claim 1.

21. The display device according to claim 20, further comprising:
a plurality of sub-pixels, located on the base substrate;
a light-splitting structure, the light-splitting structure being arranged on a light exiting side of the display substrate, and the light-splitting structure being configured to direct the light emitted by the plurality of sub-pixels to different viewpoint regions,
wherein the light-splitting structure comprises a plurality of light-splitting portions extending in the first direction and arranged in the second direction, and each of the plurality of the light-splitting portions comprises a lens.

22. A manufacturing method of a display substrate, comprising:
forming an insulating layer, a conductive layer and a plurality of second transmission portions on a base substrate, the conductive layer being located on a side of the insulating layer, the plurality of second transmission portions being located on a side of the insulating layer away from the conductive layer;
wherein forming the conductive layer comprises forming a first transmission layer, and patterning the first transmission layer to form a first pattern, and the first pattern comprises a plurality of first transmission portions;
forming the insulating layer comprises patterning the insulating layer, so that the insulating layer comprises at least one connection via hole;
forming the plurality of second transmission portions comprises forming a second transmission layer and patterning the second transmission layer to form a second pattern, and the second pattern comprises the plurality of second transmission portions,
wherein the at least one first transmission portion is electrically connected with at least one second transmission portion through at least one connection via hole, an orthographic projection of a portion of an edge of the at least one first transmission portion extending in the second direction on the base substrate falls into an orthographic projection of the connection via hole on the base substrate, the second direction intersects with the first direction.

23. The manufacturing method of the display substrate according to claim 22, wherein a portion of an edge of the at least one first transmission portion extending in the second direction on the base substrate falling into an orthographic projection of the connection via hole on the base substrate comprises:
a distance between a portion of an edge of the at least one first transmission portion extending in the second direction and the first connection via hole is set as Space, and the Space satisfies:
$$Space ⩽ \sqrt{K 1 * OL {1}^{2} + K 1 * OL {2}^{2} + Tor {1}^{2} + Tor {2}^{2}} + Bias 1 + Bias 2 ,$$
wherein OL1 refers to a minimum spacing between a line in the first transmission layer and a corresponding design position, OL2 refers to a minimum spacing between a line in the second transmission layer and a corresponding design position, Tor1 refers to a uniformity of the first pattern, Tor2 refers to a uniformity of the second pattern, Bias1 refers to a size accuracy of the first pattern, and Bias2 refers to a size accuracy of the second pattern.
